(19) United States
(12) Patent Application Publication
(10) Pub. No.: US 2026/0271592 A1
(43) Pub. Date: Sep. 10, 2026

(54) DISPLAY DEVICE, MANUFACTURING METHOD THEREOF AND ELECTRONIC DEVICE INCLUDING THE SAME

(71) Applicant: Samsung Display Co., Ltd., Yongin-si (KR)

(72) Inventors: Eun Jin KWAK, Yongin-si (KR); Soo Youn KIM, Yongin-si (KR); Eon Joo LEE, Yongin-si (KR)

(21) Appl. No.: 19/387,379

(22) Filed: Nov. 12, 2025

(30) Foreign Application Priority Data
Mar. 4, 2025 (KR) 10-2025-0027258
Jul. 15, 2025 (KR) 10-2025-0095061

(51) Int. Cl. H10K 59/80; H10K 59/12; H10K 59/122; H10K 59/40

(52) U.S. Cl. CPC H10K 59/877; H10K 59/1201; H10K 59/122; H10K 59/40

(57) ABSTRACT

Provided are a display device, a manufacturing method thereof, and an electronic device including the same. According to one or more embodiments, the display includes a substrate, pixel electrodes above the substrate, a pixel-defining film exposing portions of the pixel electrodes and defining emission areas, light-emitting layers above the pixel electrodes in the emission areas, a common electrode above the pixel-defining film and the light-emitting layers, an encapsulation layer above the common electrode and including at least one organic film and at least one inorganic film, and scattering patterns respectively in the emission areas at edges of the emission areas.

### CROSS-REFERENCE TO RELATED APPLICATIONS

The present application claims priority to, and the benefit of, Korean Patent Application No. 10-2025-0027258, filed on Mar. 4, 2025, and Korean Patent Application No. 10-2025-0095061, filed on Jul. 15, 2025, in the Korean Intellectual Property Office, the entire disclosures of which are incorporated herein by reference.

### BACKGROUND

### 1. Field

One or more embodiments of the present disclosure relate to a display device, a manufacturing method thereof, and an electronic device including the same.

### 2. Description of the Related Art

As the communication technology and the media develop, display devices have been used to display images in various places and environments. For example, various types of display devices such as liquid crystal displays (LCDs) and organic light-emitting displays (OLEDs) have been widely used.

The organic light-emitting displays (OLED) have been widely used in display devices because they have a fast response speed and a great luminance and viewing angle and are driven with low power. However, luminance of a display device may be lower when the display device is viewed from a side surface than when the display device is viewed from a front surface. In addition, a phenomenon may occur in which a great luminance change amount appears depending on an angle at which the display device is viewed.

### SUMMARY

Aspects of embodiments of the present disclosure provide a display device whose luminance may be increased when the display device is viewed from a side surface compared to when the display device is viewed from a front surface.

Aspects of embodiments of the present disclosure also provide a manufacturing method of a display device whose luminance may be increased when the display device is viewed from a side surface compared to when the display device is viewed from a front surface.

Aspects of embodiments of the present disclosure also provide an electronic device including a display device whose luminance may be increased when the display device is viewed from a side surface compared to when the display device is viewed from a front surface.

However, embodiments of the present disclosure are not limited to those set forth herein. The above and other embodiments of the present disclosure will become more apparent to one of ordinary skill in the art to which the present disclosure pertains by referencing the detailed description of the present disclosure given below.

According to one or more embodiments of the present disclosure, there is provided a display device including a substrate, pixel electrodes above the substrate, a pixel-defining film exposing portions of the pixel electrodes and defining emission areas, light-emitting layers above the pixel electrodes in the emission areas, a common electrode above the pixel-defining film and the light-emitting layers, an encapsulation layer above the common electrode and including at least one organic film and at least one inorganic film, and scattering patterns respectively in the emission areas at edges of the emission areas.

Inner circumferences of the scattering patterns may be inside the emission areas in plan view, wherein outer circumferences of the scattering patterns are outside the emission areas in plan view.

The display device may further include a touch-sensing layer above the encapsulation layer and including inorganic insulating layers and sensor electrodes, a reflection reduction member above the touch-sensing layer for reducing a reflection amount of incident external light, a window member above the reflection reduction member, and an adhesive member between the reflection reduction member and the window member, wherein the pixel electrodes include a flat portion parallel to the substrate at a central portion of a corresponding one of the pixel electrodes, and an inclined portion around the flat portion.

The scattering patterns may be between the inorganic insulating layers.

The scattering patterns may be on the inorganic insulating layers.

The scattering patterns may be between the touch-sensing layer and the reflection reduction member.

The reflection reduction member may include a polarizing member, wherein the scattering patterns are on one surface of the polarizing member.

The reflection reduction member may include color filters, wherein the scattering patterns are on the color filters.

The scattering patterns may be between the reflection reduction member and the adhesive member.

The scattering patterns may be between the adhesive member and the window member.

The reflection reduction member may include a black matrix around the emission areas in plan view, wherein the scattering patterns are spaced from the black matrix.

A shortest distance between one of the outer circumferences of one of the scattering patterns overlapping one of the pixel electrodes and an edge of the flat portion of the one of the pixel electrodes may be a first straight line, wherein a first angle between a thickness direction of the substrate and the first straight line is about 5° to about 45°.

A distance between one of the inner circumferences of the one of the scattering patterns and the edge of the flat portion of the one of the pixel electrodes that is furthest therefrom may be a second straight line, wherein a second angle between the thickness direction and the second straight line is substantially equal to the first angle.

The scattering patterns may include organic materials including scattering particles.

According to one or more embodiments of the present disclosure, there is provided an electronic device including a processor for transmitting an image data signal for displaying an image, and a display module for receiving the image data signal and for displaying the image, and including a substrate, pixel electrodes above the substrate, a pixel-defining film exposing portions of the pixel electrodes and defining emission areas, light-emitting layers above the pixel electrodes in the emission areas, a common electrode above the pixel-defining film and the light-emitting layers, an encapsulation layer above the common electrode and including at least one organic film and at least one inorganic film, and scattering patterns respectively in the emission areas, and including inner circumferences respectively inside the emission areas, and outer circumferences respectively outside the emission areas.

According to one or more embodiments of the present disclosure, there is provided a manufacturing method of a display device including sequentially forming a pixel electrode, a light-emitting layer, and a common electrode above a substrate, forming an encapsulation layer above the common electrode, forming a first inorganic insulating film above the encapsulation layer, and forming a scattering pattern above the first inorganic insulating film and at least partially overlapping the pixel electrode.

The manufacturing method may further include forming a second inorganic insulating film and a third inorganic insulating film above the scattering pattern and the first inorganic insulating film, attaching a polarizing member onto the third inorganic insulating film, attaching an adhesive member onto the polarizing member, and attaching a window member onto the adhesive member.

The manufacturing method may further include forming a second inorganic insulating film and a third inorganic insulating film above the scattering pattern and the first inorganic insulating film, forming a color filter layer including color filters above the third inorganic insulating film, attaching an adhesive member onto the color filter layer, and attaching a window member onto the adhesive member.

The forming of the pixel electrode, the light-emitting layer, and the common electrode may include forming a first intermediate layer defining a first hole above the substrate, forming a second intermediate layer above the first hole and the first intermediate layer, forming the pixel electrode including a flat portion and an inclined portion above the second intermediate layer, forming the light-emitting layer above the pixel electrode, and forming the common electrode on the light-emitting layer.

The first hole may overlap the pixel electrode in a thickness direction of the substrate.

According to the aforementioned and other embodiments of the present disclosure, scattering patterns partially overlapping emission areas are included in the display device to scatter light emitted from the emission areas, such that luminance of the display device on a side surface of the display device, as compared to a front surface of the display device, may be increased. Accordingly, the likelihood of a rapid luminance change of the display device on the side surface of the display device compared to the front surface of the display device may be reduced or prevented. Accordingly, usability of the display device when a user views the display device from the side surface of the display device may be improved.

### BRIEF DESCRIPTION OF THE DRAWINGS

The above and other embodiments of the present disclosure will become more apparent by describing embodiments thereof with reference to the attached drawings, in which:

FIG. 1 is a perspective view of a display device according to some embodiments of the present disclosure;

FIG. 2 is a plan view illustrating an example of the display device of FIG. 1;

FIG. 3 is a side view illustrating an example of the display device of FIG. 1;

FIG. 4 is a layout diagram illustrating an example of a touch-sensing layer of FIG. 3;

FIG. 5 is an enlarged layout diagram of area A of FIG. 4;

FIG. 6 is an enlarged layout diagram of area PX of FIG. 5;

FIG. 7 is a cross-sectional view illustrating an example taken along the line I-I′ of FIG. 6;

FIG. 8 is a cross-sectional view illustrating another example taken along the line I-I′ of FIG. 6;

FIG. 9 is a cross-sectional view illustrating still another example taken along the line I-I′ of FIG. 6;

FIG. 10 is a cross-sectional view illustrating still another example taken along the line I-I′ of FIG. 6;

FIG. 11 is a cross-sectional view illustrating still another example taken along the line I-I′ of FIG. 6;

FIG. 12 is a cross-sectional view illustrating still another example taken along the line I-I′ of FIG. 6;

FIG. 13 is a cross-sectional view illustrating still another example taken along the line I-I′ of FIG. 6;

FIG. 14 is a cross-sectional view illustrating still another example taken along the line I-I′ of FIG. 6;

FIG. 15 is a cross-sectional view illustrating still another example taken along the line I-I′ of FIG. 6;

FIG. 16 is a side view of a display device according to some embodiments of the present disclosure;

FIG. 17 is a layout diagram illustrating an example of the display device of FIG. 16;

FIG. 18 is a cross-sectional view illustrating an example taken along the line I-I′ of FIG. 17;

FIG. 19 is a cross-sectional view illustrating another example taken along the line I-I′ of FIG. 17;

FIG. 20 is a cross-sectional view illustrating still another example taken along the line I-I′ of FIG. 17;

FIG. 21 is a cross-sectional view illustrating still another example taken along the line I-I′ of FIG. 17;

FIG. 22 is a cross-sectional view illustrating still another example taken along the line I-I′ of FIG. 17;

FIG. 23 is a cross-sectional view illustrating still another example taken along the line I-I′ of FIG. 17;

FIG. 24 is a cross-sectional view illustrating still another example taken along the line I-I′ of FIG. 17;

FIG. 25 is a flowchart for describing a manufacturing method of a display device according to some embodiments of the present disclosure;

FIGS. 26 to 38 are cross-sectional views for describing respective processes of the manufacturing method of a display device of FIG. 25;

FIG. 39 is a flowchart for describing a manufacturing method of a display device according to some embodiments of the present disclosure;

FIGS. 40 to 42 are cross-sectional views for describing respective processes of the manufacturing method of a display device of FIG. 39;

FIG. 43 is a block diagram for describing an electronic device including a display device according to some embodiments of the present disclosure; and

FIG. 44 is an illustrative diagram for describing an electronic device including a display device according to some embodiments of the present disclosure.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object 1ortion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XY, YZ, and XZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are only used to distinguish one element, member, component, region, area, layer, section, or portion from another element, member, component, region, area, layer, section, or portion. Thus, a first element, component, region, layer, or section described below could be termed a second element, component, region, layer, or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5 % of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.” Furthermore, the expression “being the same” may mean “being substantially the same.” In other words, the expression “being the same” may include a range that can be tolerated by those of ordinary skill in the art. The other expressions may also be expressions from which “substantially” has been omitted.

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

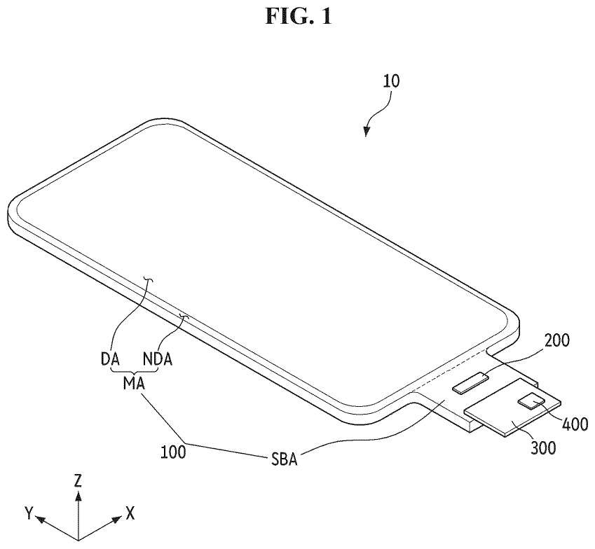

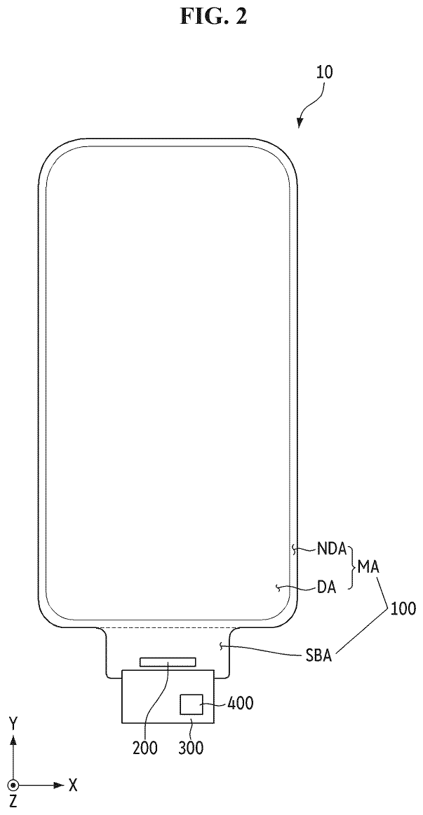

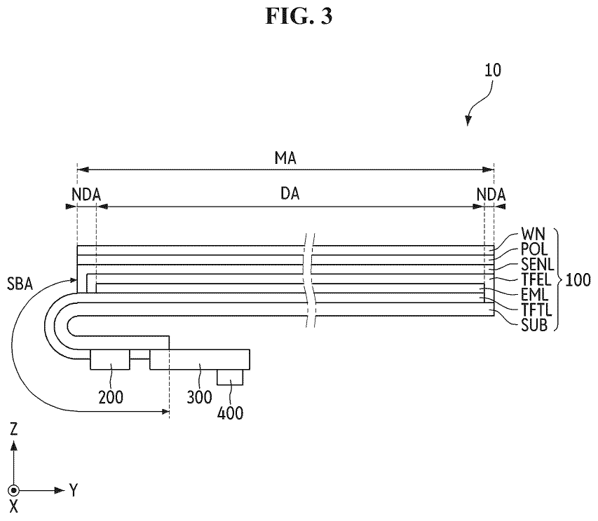

FIG. 1 is a perspective view of a display device according to some embodiments of the present disclosure. FIG. 2 is a plan view illustrating an example of the display device of FIG. 1. FIG. 3 is a side view illustrating an example of the display device of FIG. 1.

Referring to FIGS. 1 to 3, a display device 10 according to one or more embodiments may be applied to portable electronic devices, such as mobile phones, smartphones, tablet personal computers (PCs), mobile communication terminals, electronic notebooks, electronic books, portable multimedia players (PMPs), navigation devices, and ultra mobile PCs (UMPCs). Alternatively, the display device 10 according to one or more embodiments may be applied as a display unit of televisions, laptop computers, monitors, billboards, or the Internet of Things (IoTs). Alternatively, the display device 10 according to one or more embodiments may be applied to wearable devices, such as smart watches, watch phones, glasses-type displays, and head-mounted displays (HMDs). Alternatively, the display device 10 according to one or more embodiments may be applied to a center information display (CID) located on an instrument board, a center fascia, or a dashboard of a vehicle, a room mirror display substituting for a side-view mirror of the vehicle, or a display located on a rear surface of a front seat as entertainment for a rear seat of the vehicle.

The display device 10 may be a light-emitting display device, such as an organic light-emitting display using organic light-emitting diodes, a quantum dot light-emitting display including quantum dot light-emitting layers, an inorganic light-emitting display including inorganic semiconductors, and a micro light-emitting display using micro or nano light-emitting diodes (micro LEDs or nano LEDs). Hereinafter, it will be mainly described that the display device 10 is the organic light-emitting display, but the present disclosure is not limited thereto.

The display device 10 may include a display panel 100, a display-driving circuit 200, a display circuit board 300, and a touch-driving circuit 400.

The display panel 100 may be formed in a rectangular shape, in plan view, having short sides in a first direction (X-axis direction), and long sides in a second direction (Y-axis direction) crossing the first direction (X-axis direction). A corner where the short side in the first direction (X-axis direction) and the long side in the second direction (Y-axis direction) meet may be rounded with a selected curvature or right-angled. A shape of the display panel 100 in plan view is not limited to the rectangular shape, and may be other polygonal shapes, a circular shape, or an elliptical shape. The display panel 100 may be flat, but is not limited thereto. For example, the display panel 100 includes curved surface portions formed at left and right ends thereof and having a constant curvature or a variable curvature. In addition, the display panel 100 may be flexibly formed to be curved, bent, folded, or rolled.

The display panel 100 may include a main area MA and a sub-area SBA.

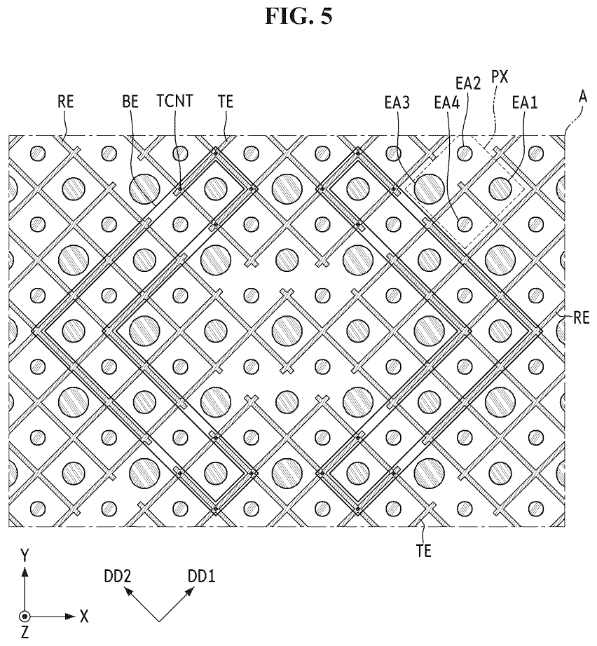

The main area MA may include a display area DA displaying an image and a non-display area NDA, which is a peripheral area of the display area DA. The display area DA may include pixels PX (see FIG. 5) displaying the image. The sub-area SBA may protrude from one side of the main area MA in a direction opposite to the second direction (Y-axis direction).

It has been illustrated in FIGS. 1 and 2 that the sub-area SBA is unbent, but the sub-area SBA may be bent as illustrated in FIG. 3, and in this case, the sub-area SBA may be located on a lower surface of the display panel 100. When the sub-area SBA is bent, the sub-area SBA may overlap the main area MA in a thickness direction (Z-axis direction) of a substrate SUB. The display-driving circuit 200 may be located in the sub-area SBA.

In addition, the display panel 100 may include a substrate SUB, a thin film transistor layer TFTL, a light-emitting element layer EML, an encapsulation layer TFEL, a touch-sensing layer SENL, a polarizing member POL, and a window member WN, as illustrated in FIG. 3.

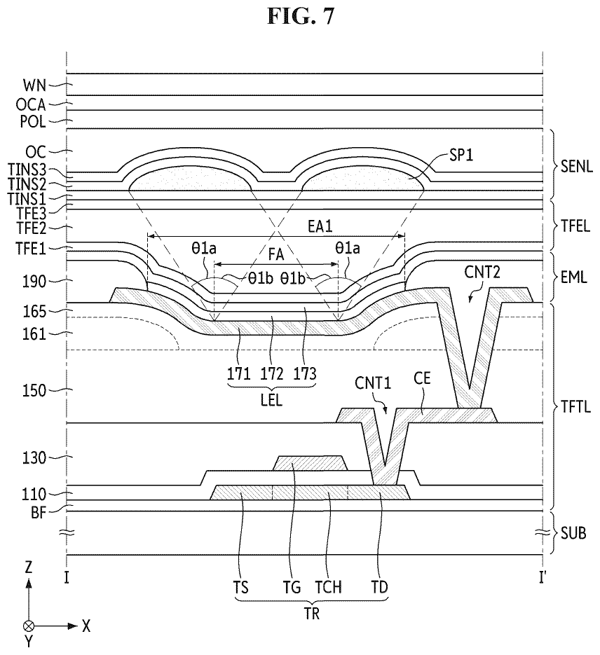

The thin film transistor layer TFTL may be located on the substrate SUB (as used herein, “located on” or “on” may mean “above” or may mean “below”). The thin film transistor layer TFTL may be located in the main area MA and the sub-area SBA. The thin film transistor layer TFTL may include transistors TR (see FIG. 7).

The light-emitting element layer EML may be located on the thin film transistor layer TFTL. The light-emitting element layer EML may be located in the display area DA of the main area MA. The light-emitting element layer EML may include light-emitting elements LEL (see FIG. 7) located in emission areas.

The encapsulation layer TFEL may be located on the light-emitting element layer EML. The encapsulation layer TFEL may be located in the display area DA and the non-display area NDA of the main area MA. The encapsulation layer TFEL may include at least one inorganic film and at least one organic film for encapsulating the light-emitting element layer EML.

The touch-sensing layer SENL may be located on the encapsulation layer TFEL. The touch-sensing layer SENL may be located in the display area DA and the non-display area NDA of the main area MA. The touch-sensing layer SENL may sense a touch of a person or an object using sensor electrodes.

The polarizing member POL may be located on the touch-sensing layer SENL. The polarizing member POL may be located in the display area DA and the non-display area NDA of the main area MA. The polarizing member POL may include, for example, a polarizing film or a polarizing plate. The polarizing member POL may reduce or prevent reflection of light incident from the outside of the display device 10 to be viewed by a user. For example, the polarizing member POL may be referred to as a reflection reduction member.

The window member WN may be located on the polarizing member POL. The window member WN may be located in the display area DA and the non-display area NDA of the main area MA. The window member WN may protect an upper portion of the display panel 100.

The display-driving circuit 200 may generate signals and voltages for driving the display panel 100. The display-driving circuit 200 may be formed as an integrated circuit (IC) and attached onto the display panel 100 in a chip-on-glass (COG) manner, a chip-on-plastic (COP) manner, or an ultrasonic bonding manner, but is not limited thereto. For example, the display-driving circuit 200 may be attached onto the display circuit board 300 in a chip-on-film (COF) manner.

The display circuit board 300 may be attached to one end of the sub-area SBA of the display panel 100. For this reason, the display circuit board 300 may be electrically connected to the display panel 100 and the display-driving circuit 200. The display panel 100 and the display-driving circuit 200 may receive digital video data, timing signals, and driving voltages through the display circuit board 300. The display circuit board 300 may be a flexible printed circuit board, a printed circuit board, or a flexible film, such as a chip on film.

The touch-driving circuit 400 may be electrically connected to the sensor electrodes of the touch-sensing layer SENL of the display panel 100. The touch-driving circuit 400 applies driving signals to the sensor electrodes of the touch-sensing layer SENL, and measures mutual capacitance values of the sensor electrodes. The driving signal may be a signal having a plurality of driving pulses. The touch-driving circuit 400 may decide whether or not a user has performed a touch, and whether or not the user has approached the display device according to the mutual capacitance values. The touch of the user indicates that a user's finger or an object, such as a pen comes into direct contact with one surface of the display device 10 located on the touch-sensing layer SENL. The approach of the user indicates that the user's finger or the object, such as the pen hovers above one surface of the display device 10.

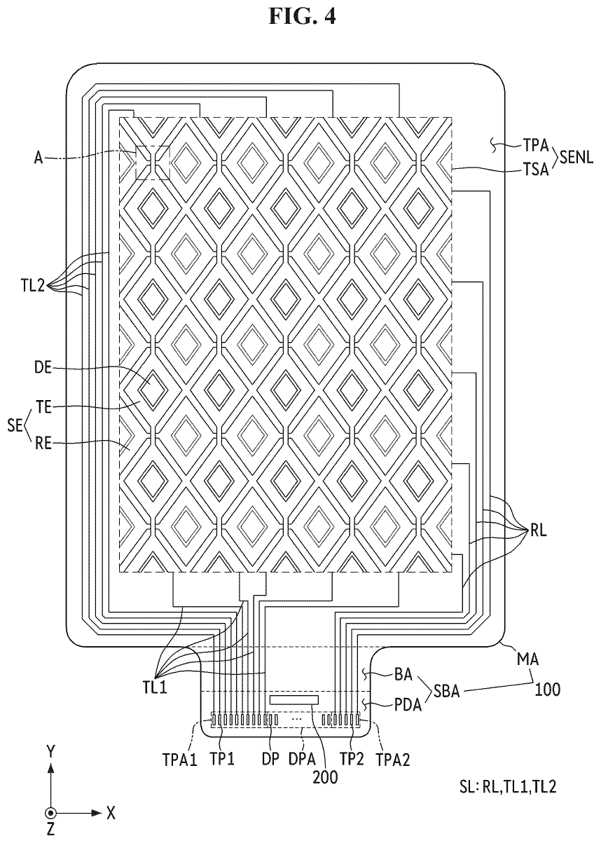

FIG. 4 is a layout diagram illustrating an example of a touch-sensing layer of FIG. 3.

It has been mainly described in FIG. 4 that sensor electrodes SE of the touch-sensing layer SENL include two types of electrodes, such as driving electrodes TE and sensing electrodes RE, and are driven in a mutual capacitive manner of sensing charges charged in mutual capacitance through the sensing electrodes RE after applying driving signals to the driving electrodes TE, but the present disclosure is not limited thereto.

In FIG. 4, for convenience of explanation, only the driving electrodes TE, the sensing electrodes RE, dummy patterns DE, sensor lines TL1, TL2, and RL, and sensor pads TP1 and TP2 have been illustrated.

Referring to FIG. 4, the touch-sensing layer SENL includes a touch sensor area TSA for sensing a user's touch and a touch peripheral area TPA located around the touch sensor area TSA. The touch sensor area TSA may overlap the display area DA of FIG. 1, and the touch peripheral area TPA may overlap the non-display area NDA of FIG. 1.

The touch sensor area TSA includes the driving electrodes TE, the sensing electrodes RE, and the dummy patterns DE. The driving electrodes TE and the sensing electrodes RE may be electrodes for forming mutual capacitance to sense a touch of an object or a person.

The sensing electrodes RE may be arranged side by side in the first direction (X-axis direction) and the second direction (Y-axis direction). The sensing electrodes RE may be electrically connected to each other in the first direction (X-axis direction). The sensing electrodes RE adjacent to each other in the first direction (X-axis direction) may be connected to each other. The sensing electrodes RE adjacent to each other in the second direction (Y-axis direction) may be electrically disconnected from each other.

The driving electrodes TE may be arranged side by side in the first direction (X-axis direction) and the second direction (Y-axis direction). The driving electrodes TE adjacent to each other in the first direction (X-axis direction) may be electrically disconnected from each other. The driving electrodes TE may be electrically connected to each other in the second direction (Y-axis direction). For example, the driving electrodes TE adjacent to each other in the second direction (Y-axis direction) may be connected to each other through a touch connection electrode BE as illustrated in FIG. 5.

Each of the dummy patterns DE may be surrounded by the driving electrode TE or the sensing electrode RE. Each of the dummy patterns DE may be electrically disconnected from the driving electrode TE or the sensing electrode RE. Each of the dummy patterns DE may be spaced apart from the driving electrode TE or the sensing electrode RE. Each of the dummy patterns DE may be electrically floated.

It has been illustrated in FIG. 4 that each of the driving electrodes TE, the sensing electrodes RE, and the dummy patterns DE has a rhombic shape in plan view, but the present disclosure is not limited thereto. For example, each of the driving electrodes TE, the sensing electrodes RE, and the dummy patterns DE may have a quadrangular shape other than the rhombic shape, a polygonal shape other than the quadrangular shape, a circular shape, or an elliptical shape in plan view.

The sensor lines TL1, TL2, and RL may be located in the touch peripheral area TPA. The sensor lines TL1, TL2, and RL include sensing lines RL connected to the sensing electrodes RE and first driving lines TL1 and second driving lines TL2 connected to driving electrodes TE.

The sensing electrodes RE located on one side of the touch sensor area TSA may be connected to the sensing lines RL in a one-to-one manner. For example, as illustrated in FIG. 4, sensing electrodes RE located at a right end among the sensing electrodes RE electrically connected to each other in the first direction (X-axis direction) may be connected to the sensing lines RL. The sensing lines RL may be connected to second sensor pads TP2 in a one-to-one manner. Therefore, the touch-driving circuit 400 may be electrically connected to the sensing electrodes RE.

The driving electrodes TE located on one side of the touch sensor area TSA may be connected to the first driving lines TL1 in a one-to-one manner, and the driving electrodes TE located on the other side of the touch sensor area TSA may be connected to the second driving lines TL2 in a one-to-one manner. For example, as illustrated in FIG. 4, driving electrodes TE located at a lower end among the driving electrodes TE electrically connected to each other in the second direction (Y-axis direction) may be connected to the first driving lines TL1, and driving electrodes TE located at an upper end among the driving electrodes TE electrically connected to each other in the second direction (Y-axis direction) may be connected to the second driving lines TL2. The second driving lines TL2 may be connected to the driving electrodes TE on the upper side of the touch sensor area TSA via the outer left side of the touch sensor area TSA.

The first driving lines TL1 and the second driving lines TL2 may be connected to first sensor pads TP1 in a one-to-one manner. Therefore, the touch-driving circuit 400 may be electrically connected to the driving electrodes TE. Because the driving electrodes TE are connected to the driving lines TL1 and TL2 respectively on opposite sides of the touch sensor area TSA to receive touch-driving signals, the likelihood of a difference between the touch-driving signal applied to the driving electrodes TE located on a lower side of the touch sensor area TSA, and the touch-driving signal applied to the driving electrodes TE located on an upper side of the touch sensor area TSA (e.g., due to an RC delay of the touch-driving signals), may be reduced or prevented.

A first sensor pad area TPA1 where the first sensor pads TP1 are located may be located on one side of a display pad area DPA where display pads DP are located. A second sensor pad area TPA2 where the second sensor pads TP2 are located may be located on the other side of the display pad area DPA. The display pads DP may be electrically connected to data lines of the display panel 100.

The display pad area DPA, the first sensor pad area TPA1, and the second sensor pad area TPA2 may correspond to pads of the display panel 100 connected to the display circuit board 300 illustrated in FIG. 1. The display circuit board 300 may be located on the display pads DP, the first sensor pads TP1, and the second sensor pads TP2. The display pads DP, the first sensor pads TP1, and the second sensor pads TP2 may be electrically connected to the display circuit board 300 using a low-resistance and high-reliability material, such as an anisotropic conductive film or a self-assembly anisotropic conductive paste (SAP). Therefore, the display pads DP, the first sensor pads TP1, and the second sensor pads TP2 may be electrically connected to the touch-driving circuit 400 located on the display circuit board 300.

FIG. 5 is an enlarged layout diagram of area A of FIG. 4.

Referring to FIG. 5, the driving electrodes TE and the sensing electrodes RE are located at a same layer, and may thus be spaced apart from each other. That is, a gap may be formed between the driving electrode TE and the sensing electrode RE adjacent to each other.

In addition, the dummy patterns DE may be located at a same layer as the driving electrodes TE and the sensing electrodes RE. That is, a gap may be formed between the driving electrode TE and the dummy pattern DE adjacent to each other, and between the sensing electrode RE and the dummy pattern DE adjacent to each other.

The touch connection electrodes BE may be located at a different layer from the driving electrodes TE and the sensing electrodes RE. The touch connection electrode BE may be bent at least once. It has been illustrated in FIG. 5 that the touch connection electrode BE has a crimp shape (e.g., shaped like “<” or “>”), but a shape of the touch connection electrode BE in plan view is not limited thereto. Because the driving electrodes TE adjacent to each other in the second direction (Y-axis direction) are connected to each other by a plurality of connection electrodes BE, even though any one of the touch connection electrodes BE is disconnected, the driving electrodes TE adjacent to each other in the second direction (Y-axis direction) may be stably connected to each other. It has been illustrated in FIG. 5 that the driving electrodes TE adjacent to each other are connected to each other by two connection electrodes BE, but the number of connection electrodes BE is not limited thereto.

The touch connection electrode BE may overlap the driving electrodes TE adjacent each other in the second direction (Y-axis direction), in a third direction (Z-axis direction), which is the thickness direction of the substrate SUB. The touch connection electrode BE may overlap the sensing electrode RE in the third direction (Z-axis direction). One side of the touch connection electrode BE may be connected to any one of the driving electrodes TE adjacent to each other in the second direction (Y-axis direction) through touch contact holes TCNT. The other side of the touch connection electrode BE may be connected to the other of the driving electrodes TE adjacent to each other in the second direction (Y-axis direction) through touch contact holes TCNT.

Due to the touch connection electrodes BE, the driving electrodes TE and the sensing electrodes RE may be electrically disconnected from each other at intersection portions between the driving electrodes TE and the sensing electrodes RE. For this reason, mutual capacitance may be formed between the driving electrodes TE and the sensing electrodes RE.

Each of the driving electrodes TE, the sensing electrodes RE, and the touch connection electrodes BE may have a mesh structure or a net structure in plan view. In addition, each of the dummy patterns DE may have a mesh structure or a net structure in plan view. For this reason, each of the driving electrodes TE, the sensing electrodes RE, the touch connection electrodes BE, and the dummy patterns DE may be spaced apart from emission areas EA1 to EA4 of each of the pixels PX. Therefore, it is possible to reduce or prevent the likelihood of a phenomenon in which light emitted from the emission areas EA1 to EA4 is blocked by the driving electrodes TE, the sensing electrodes RE, the touch connection electrodes BE, and the dummy patterns DE, and accordingly, luminance of the light is decreased.

The display panel 100 may include the pixels PX. The pixel PX may be a minimum unit capable of displaying white light. Each of the pixels PX may include a first emission area EA1, a second emission area EA2, a third emission area EA3, and a fourth emission area EA4. However, the present disclosure is not limited thereto, and the number of emission areas included in one pixel PX may be modified.

The first emission area EA1 may emit light of a first color. The first color may be red, and a peak wavelength of the light of the first color may be included in a wavelength band of approximately 600 nm to approximately 750 nm.

The second emission area EA2 may emit light of a second color. The second color may be green, and a peak wavelength of the light of the second color may be included in a wavelength band of approximately 500 nm to approximately 570 nm.

The third emission area EA3 may emit light of a third color. The third color may be blue, and a peak wavelength of the light of the third color may be included in a wavelength band of approximately 430 nm to approximately 490 nm.

The fourth emission area EA4 may emit light of a second color, similar to the second emission area EA2.

As an example, the emission areas EA1 to EA4 may be located in a PenTile™ type (PenTile™ being a registered trademark of Samsung Display Co., Ltd., Republic of Korea). The first emission area EA1 may be spaced apart from the second emission area EA2 in a second diagonal direction DD2. The first emission area EA1 may be spaced apart from the third emission area EA3 in the first direction (X-axis direction). The first emission area EA1 may be spaced apart from the fourth emission area EA4 in a first diagonal direction DD1. The second emission area EA2 may be spaced apart from the third emission area EA3 in the first diagonal direction DD1. The second emission area EA2 may be spaced apart from the fourth emission area EA4 in the second direction (Y-axis direction). The third emission area EA3 may be spaced apart from the fourth emission area EA4 in the second diagonal direction DD2.

It has been illustrated in FIG. 5 that a shape of each of the emission areas EA1 to EA4 in plan view is a circular shape, but the present disclosure is not limited thereto. The shape of each of the emission areas EA1 to EA4 in plan view may be variously modified into an elliptical shape, a rectangular shape, or the like.

Areas of the emission areas EA1 to EA4 may be different from each other. As an example, an area of the first emission area EA1 may be greater than an area of the second emission area EA2, and smaller than an area of the third emission area EA3. The area of the second emission area EA2 may be the same as an area of the fourth emission area EA4. However, the present disclosure is not limited thereto, and sizes of the respective emission areas EA1 to EA4 may be freely adjusted.

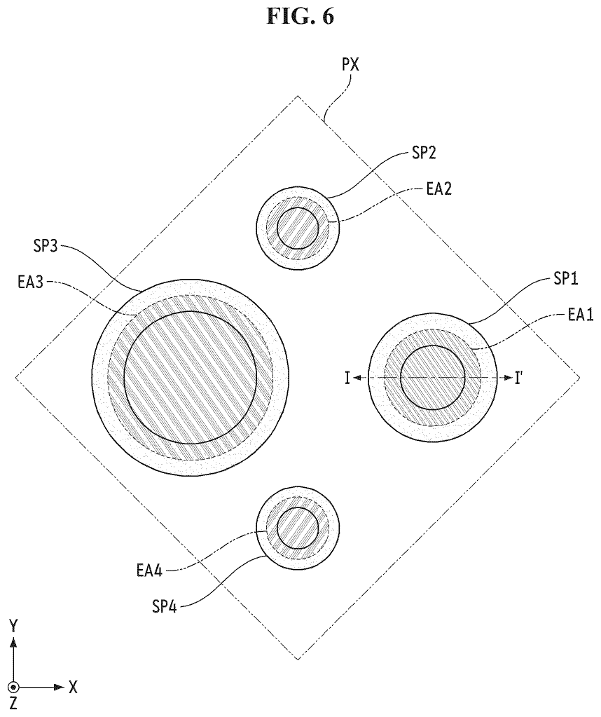

FIG. 6 is an enlarged layout diagram of area PX of FIG. 5.

Referring to FIG. 6, the pixel PX may further include a first scattering pattern SP1, a second scattering pattern SP2, a third scattering pattern SP3, and a fourth scattering pattern SP4.

The first scattering pattern SP1 may be located at an edge of the first emission area EA1. An outer circumference of the first scattering pattern SP1 may be located outside the first emission area EA1. An inner circumference of the first scattering pattern SP1 may be located inside the first emission area EA1. A shape of the first scattering pattern SP1 in plan view may follow a shape of the first emission area EA1 in plan view.

The second scattering pattern SP2 may be located at an edge of the second emission area EA2. An outer circumference of the second scattering pattern SP2 may be located outside the second emission area EA2. An inner circumference of the second scattering pattern SP2 may be located inside the second emission area EA2. A shape of the second scattering pattern SP2 in plan view may follow a shape of the second emission area EA2 in plan view.

The third scattering pattern SP3 may be located at an edge of the third emission area EA3. An outer circumference of the third scattering pattern SP3 may be located outside the third emission area EA3. An inner circumference of the third scattering pattern SP3 may be located inside the third emission area EA3. A shape of the third scattering pattern SP3 in plan view may follow a shape of the third emission area EA3 in plan view.

The fourth scattering pattern SP4 may be located at an edge of the fourth emission area EA4. An outer circumference of the fourth scattering pattern SP4 may be located outside the fourth emission area EA4. An inner circumference of the fourth scattering pattern SP4 may be located inside the fourth emission area EA4. A shape of the fourth scattering pattern SP4 in plan view may follow a shape of the fourth emission area EA4 in plan view.

An example in which a shape of each of the emission areas EA1 to EA4 in plan view is a circular shape and a shape of each of the scattering patterns SP1 to SP4 in plan view is a doughnut shape (e.g., a ring-like shape, or toroidal shape) has been illustrated in FIG. 6, but the present disclosure is not limited thereto. As an example, when a shape of each of the emission areas EA1 to EA4 in plan view is a quadrangular shape, a shape of each of the scattering patterns SP1 to SP4 in plan view may be a quadrangular band shape. As described above, the shape of each of the scattering patterns SP1 to SP4 in plan view may be modified according to the shape of each of the emission areas EA1 to EA4 in plan view.

The first scattering pattern SP1 may scatter the light of the first color emitted from the first emission area EA1. The second scattering pattern SP2 may scatter the light of the second color emitted from the second emission area EA2. The third scattering pattern SP3 may scatter the light of the third color emitted from the third emission area EA3. The fourth scattering pattern SP4 may scatter the light of the fourth color emitted from the fourth emission area EA4. Accordingly, luminance of the display device 10 on a side surface of the display device 10 compared to a front surface of the display device 10 may be increased. In addition, a luminance change amount of the display device 10 on the side surface of the display device 10 compared to the front surface of the display device may be reduced, such that a rapid luminance change depending on a viewing angle may be reduced or prevented.

FIG. 7 is a cross-sectional view illustrating an example taken along the line I-I′ of FIG. 6.

Referring to FIG. 7, the display panel 100 may include a substrate SUB, a thin film transistor layer TFTL, a light-emitting element layer EML, an encapsulation layer TFEL, a touch-sensing layer SENL, a polarizing member POL, an adhesive member OCA, and a window member WN.

The substrate SUB may be made of an insulating material, such as glass, quartz, or a polymer resin. Alternatively, the substrate SUB may include a metal material. The substrate SUB may be a rigid substrate or be a flexible substrate that may be bent, folded, and rolled. When the substrate SUB is the flexible substrate, the substrate SUB may be made of polyimide PI, but is not limited thereto.

The thin film transistor layer TFTL may be located on the substrate SUB. The thin film transistor layer TFTL may include thin film transistors TR of each of the pixels PX, a connection electrode CE, and a plurality of insulating films.

For example, a buffer film BF may be located on the substrate SUB (as used herein, “located on” may mean “above,” or may mean “below”). The buffer film BF may include a plurality of inorganic films that are alternately stacked. For example, the buffer film BF may be formed as multiple films in which one or more inorganic films of a silicon nitride layer, a silicon oxynitride layer, a silicon oxide layer, a titanium oxide layer, and an aluminum oxide layer are alternately stacked.

An active layer of each of the thin film transistors TR may be located on the buffer film BF. The active layer may include a channel TCH, a source electrode TS, and a drain electrode TD.

A gate-insulating film 110 may be located on the active layer. The gate-insulating film 110 may be formed as an inorganic insulating film, such as a silicon nitride (SiNₓ) film, a silicon oxide (SiOₓ) film, a silicon oxynitride (SiON) film, a titanium oxide (TiOₓ) film, or an aluminum oxide (AlOₓ) film.

A gate electrode TG of a transistor TR may be located on the gate-insulating film 110. The gate electrode TG may overlap the channel TCH in the third direction (Z-axis direction). The gate electrode TG may be formed as a single layer or multiple layers made of any one of molybdenum (Mo), aluminum (Al), chromium (Cr), gold (Au), titanium (Ti), nickel (Ni), neodymium (Nd), or copper (Cu), or alloys thereof.

An interlayer insulating film 130 may be located on the gate electrode TG of the transistor TR. The interlayer insulating film 130 may be formed as an inorganic film, such as a silicon nitride layer, a silicon oxynitride layer, a silicon oxide layer, a titanium oxide layer, or an aluminum oxide layer. The interlayer insulating film 130 may be formed as a plurality of inorganic films.

A first source metal layer may be located on the interlayer insulating film 130. The first source metal layer may include the connection electrode CE. The connection electrode CE may be connected to the drain electrode TD of the transistor TR through a first contact hole CNT1 penetrating through the gate-insulating film 110 and the interlayer insulating film 130. The connection electrode CE may be formed as a single layer or multiple layers made of any one of molybdenum (Mo), aluminum (Al), chromium (Cr), gold (Au), titanium (Ti), nickel (Ni), neodymium (Nd), or copper (Cu), or alloys thereof.

A protective film 150 for planarizing a step caused by the transistor TR and protecting the transistor TR may be located on the first source metal layer. The protective film 150 may be formed as an organic film made of an acrylic resin, an epoxy resin, a phenolic resin, a polyamide resin, a polyimide resin, or the like.

A first intermediate layer 161 and a second intermediate layer 165 for forming a flat portion and an inclined portion in a pixel electrode 171 may be located on the protective film 150. The first intermediate layer 161 may include (e.g., may define) a first hole. The second intermediate layer 165 may be located on the first hole and the first intermediate layer 161. The second intermediate layer 165 may have a gentle inclination on the first hole. The first intermediate layer 161 and the second intermediate layer 165 may be formed as organic films made of an acrylic resin, an epoxy resin, a phenolic resin, a polyamide resin, a polyimide resin, or the like.

In some embodiments, the protective film 150 and the first intermediate layer 161 may be made of the same material. Accordingly, a boundary between the protective film 150 and the first intermediate layer 161 may not be viewed.

In some embodiments, the first intermediate layer 161 and the second intermediate layer 165 may be made of the same material. Accordingly, a boundary between the first intermediate layer 161 and the second intermediate layer 165 may not be viewed.

The light-emitting element layer EML including a light-emitting element LEL and a pixel-defining film 190 may be located on the second intermediate layer 165. Each of the light-emitting elements LEL may include a pixel electrode 171, a light-emitting layer 172, and a common electrode 173.

For example, a pixel electrode layer may be located on the second intermediate layer 165. The pixel electrode layer may include the pixel electrode 171. The pixel electrode 171 may include a flat portion FA that is substantially parallel to the substrate SUB, and an inclined portion located around the flat portion (e.g., around in plan view). The pixel electrode 171 may be connected to the connection electrode CE through a second contact hole CNT2 penetrating through the protective film 150, the first intermediate layer 161, and the second intermediate layer 165. In a top emission structure in which light is emitted toward the common electrode 173 based on the light-emitting layer 172, the pixel electrode 171 may be formed as a single layer made of molybdenum (Mo), titanium (Ti), copper (Cu), or aluminum (Al) or formed as a stacked structure (Ti/Al/Ti) of aluminum and titanium, a stacked structure (ITO/Al/ITO) of aluminum and indium tin oxide (ITO), an APC alloy, and a stacked structure (ITO/APC/ITO) of an APC alloy and ITO to increase reflectivity. The APC alloy is an alloy of silver (Ag), palladium (Pd), and copper (Cu).

The pixel-defining film 190 may be located on a portion of the pixel electrode 171. The pixel-defining film 190 serves to define the emission areas EA1 to EA4 of the pixels PX. The pixel-defining film 190 may be formed on the second intermediate layer 165 so as to expose a partial area of the pixel electrode 171. The pixel-defining film 190 may cover edges of the pixel electrodes 171. The pixel-defining film 190 may be formed as an organic film made of an acrylic resin, an epoxy resin, a phenolic resin, a polyamide resin, a polyimide resin, or the like.

The light-emitting layer 172 may be located on the pixel electrode 171. The light-emitting layer 172 may be an organic light-emitting layer including an organic material. In this case, the light-emitting layer 172 may include a hole-transporting layer, an organic light-emitting layer, and an electron-transporting layer. When a selected voltage is applied to the pixel electrode 171 through the thin film transistor TR of the thin film transistor layer TFTL, and a cathode voltage is applied to the common electrode 173, holes and electrons move to the organic light-emitting layer through the hole-transporting layer and the electron-transporting layer, respectively, and are combined with each other in the organic light-emitting layer to emit light. The pixels PX of the light-emitting element layer EML may be located in the display area DA.

The common electrode 173 may be located on the pixel-defining film 190 and the light-emitting layer 172. The common electrode 173 may cover the light-emitting layer 172. The common electrode 173 may be a common layer formed in common in the emission areas EA1 to EA4.

The encapsulation layer TFEL may be located on the light-emitting element layer EML. The encapsulation layer TFEL may include a first inorganic encapsulation layer TFE1 and a second inorganic encapsulation layer TFE3 that reduce or prevent oxygen or moisture from penetrating into the light-emitting element layer EML. Each of the first inorganic encapsulation layer TFE1 and the second inorganic encapsulation layer TFE3 may be a silicon nitride layer, a silicon oxynitride layer, a silicon oxide layer, a titanium oxide layer, or an aluminum oxide layer, but are not limited thereto.

In addition, the encapsulation layer TFEL may include an organic encapsulation layer TFE2 serving to protect the light-emitting element layer EML from foreign substances, such as dust. The organic encapsulation layer TFE2 may be located between the first inorganic encapsulation layer TFE1 and the second inorganic encapsulation layer TFE3. The organic encapsulation layer TFE2 may be made of an acrylic resin, an epoxy resin, a phenolic resin, a polyamide resin, or a polyimide resin, but is not limited thereto.

The encapsulation layer TFEL may be located in both the display area DA and the non-display area NDA. For example, the encapsulation layer TFEL may cover the light-emitting element layer EML of the display area DA and the non-display area NDA and cover the thin film transistor layer TFTL of the non-display area NDA.

The touch-sensing layer SENL may be located on the encapsulation layer TFEL. The touch-sensing layer SENL may include a first touch-insulating film TINS1, scattering patterns SP1 to SP4, a touch connection electrode BE, a second touch-insulating film TINS2, a driving electrode TE, a sensing electrode RE, a third touch-insulating film TINS3, a black matrix BM, and an overcoat OC.

The first touch-insulating film TINS1 may be located on the encapsulation layer TFEL. The first touch-insulating film TINS1 may be inorganic film, such as a silicon nitride layer, a silicon oxynitride layer, a silicon oxide layer, a titanium oxide layer, or an aluminum oxide layer, but is not limited thereto.

The scattering patterns SP1 to SP4 may be located on the first touch-insulating film TINS1. Flat portions of the scattering patterns SP1 to SP4 may be in contact with the first touch-insulating film TINS1, and convex portions of the scattering patterns SP1 to SP4 may be in contact with the second touch-insulating film TINS2. Each of the scattering patterns SP1 to SP4 may include a photosensitive organic material including scattering particles. As an example, the scattering particles may include silicon dioxide (SiO₂) or titanium dioxide (TiO₂), but are not limited thereto. The scattering patterns SP1 to SP4 may be located around the corresponding emission areas EA1 to EA4, respectively. The first scattering pattern SP1 may partially overlap the first emission area EA1 in the third direction (Z-axis direction). The second scattering pattern SP2 may partially overlap the second emission area EA2 in the third direction (Z-axis direction). The third scattering pattern SP3 may partially overlap the third emission area EA3 in the third direction (Z-axis direction). The fourth scattering pattern SP4 may partially overlap the fourth emission area EA4 in the third direction (Z-axis direction).

In FIG. 7, the first scattering pattern SP1 and the first emission area EA1 corresponding to the first scattering pattern SP1 will be described by way of example. The second scattering pattern SP2, the third scattering pattern SP3, and the fourth scattering pattern SP4 may be formed in the same manner as the first scattering pattern SP1.

As an example, a cross section of the first scattering pattern SP1 may have a shape of two arches, but is not limited thereto. As another example, a cross section of the first scattering pattern SP1 may have an asymmetrical shape in which it has a linear slope formed in an inner circumferential direction and is convex in an outer circumferential direction. Conversely, a cross section of the first scattering pattern SP1 may have an asymmetrical shape in which it is convex in an inner circumferential direction and has a linear slope formed in an outer circumferential direction. As still another example, a cross section of the first scattering pattern SP1 may have a shape in which a rectangle is combined under an arch shape. To increase scattering, a cross-sectional shape of the first scattering pattern SP1 may be modified according to directivity.

An angle between a straight line connecting an outer circumference of the first scattering pattern SP1 and an edge of the flat portion FA of the pixel electrode 171 to each other at the shortest distance (e.g., as used herein, a first straight line from a portion of an outer circumference to a portion of an edge of the flat portion FA that is closest thereto) and the third direction (Z-axis direction) may be a first outer circumference angle θ1a. As an example, the first outer circumference angle θ1a may be about 5° to about 45°.

An angle between a straight line connecting an inner circumference of the first scattering pattern SP1 and the edge of the flat portion FA of the pixel electrode 171 to each other at the longest distance (e.g., as used herein, a second straight line from a portion of an inner circumference to a portion of a corresponding edge of the flat portion furthest therefrom) and the third direction (Z-axis direction) may be a first inner circumference angle θ1b. The first inner circumference angle θ1b may be substantially the same as the first outer circumference angle θ1a.

The touch connection electrode BE may be located on the first touch-insulating film TINS1. The touch connection electrode BE may be spaced apart from the scattering patterns SP1 to SP4 in the third direction (Z-axis direction). The touch connection electrode BE may overlap the pixel-defining film 190 in the third direction (Z-axis direction). The touch connection electrode BE may be formed as a single layer or multiple layers made of any one of molybdenum (Mo), aluminum (Al), chromium (Cr), gold (Au), titanium (Ti), nickel (Ni), neodymium (Nd), or copper (Cu), or alloys thereof.

The second touch-insulating film TINS2 may be located on the touch connection electrode BE, the scattering patterns SP1 to SP4, and the first touch-insulating film TINS1. The second touch-insulating film TINS2 may be formed as an inorganic film, such as a silicon nitride layer, a silicon oxynitride layer, a silicon oxide layer, a titanium oxide layer, or an aluminum oxide layer.

The driving electrode TE and the sensing electrode RE may be located on the second touch-insulating film TINS2. In addition, the dummy patterns DE, the first driving lines TL1, the second driving lines TL2, and the sensing lines RL illustrated in FIG. 4 as well as the driving electrode TE and sensing electrode RE, may be located on the second touch-insulating film TINS2.

The driving electrode TE and sensing electrode RE may overlap the touch connection electrode BE in the third direction (Z-axis direction). The driving electrode TE may be connected to the touch connection electrode BE through a touch contact hole TCNT (e.g., see FIG. 5) penetrating through the second touch-insulating film TINS2.

The third touch-insulating film TINS3 may be located on the driving electrode TE, the sensing electrode RE, and the second touch-insulating film TINS2. The third touch-insulating film TINS3 may be formed as an inorganic film, such as a silicon nitride layer, a silicon oxynitride layer, a silicon oxide layer, a titanium oxide layer, or an aluminum oxide layer.

The black matrix may be located on the third touch-insulating film TINS3. The black matrix may be formed using a material absorbing visible light, such as a metal material or a resin material including a pigment or a dye. The black matrix may overlap the driving electrode TE and the sensing electrode RE in the third direction (Z-axis direction). The black matrix may reduce or prevent visibility of the driving electrode TE and the sensing electrode RE from the outside.

The overcoat OC may be located on the black matrix and the third touch-insulating film TINS3. The overcoat OC may planarize a step caused by the black matrix and the scattering patterns SP1 to SP4. The overcoat OC may be formed as an organic film made of an acrylic resin, an epoxy resin, a phenolic resin, a polyamide resin, a polyimide resin, or the like.

The polarizing member POL may be located on the overcoat OC. The adhesive member OCA may be located on the polarizing member POL. The adhesive member OCA may be a transparent adhesive member, such as an optically clear adhesive film or an optically clear resin. The window member WN may be located on the adhesive member OCA.

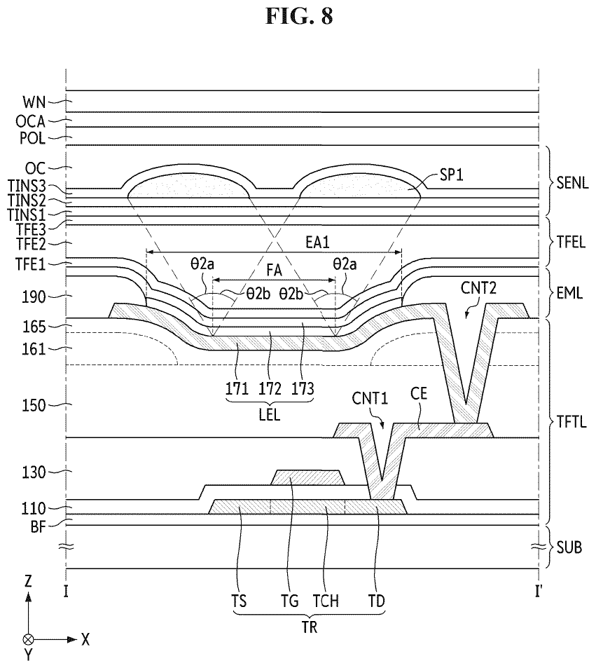

FIG. 8 is a cross-sectional view illustrating another example taken along the line I-I′ of FIG. 6. A description of contents overlapping the contents described above will be omitted or briefly provided, and contents different from the contents described above will be mainly described.

Referring to FIG. 8, the display panel 100 may include a substrate SUB, a thin film transistor layer TFTL, a light-emitting element layer EML, an encapsulation layer TFEL, a touch-sensing layer SENL, a polarizing member POL, an adhesive member OCA, and a window member WN.

In comparison with FIG. 7, which depicts the first scattering pattern SP1 located between the first touch-insulating film TINS1 and the second touch-insulating film TINS2, the first scattering pattern SP1 instead may be located between the second touch-insulating film TINS2 and the third touch-insulating film TINS3 in FIG. 8. For example, a flat portion of the first scattering pattern SP1 may be in contact with the second touch-insulating film TINS2, and a convex portion of the first scattering pattern SP1 may be in contact with the third touch-insulating film TINS3.

An angle between a straight line connecting an outer circumference of the first scattering pattern SP1 and an edge of the flat portion FA of the pixel electrode 171 to each other at the shortest distance and the third direction (Z-axis direction) may be a second outer circumference angle θ2a. As an example, the second outer circumference angle θ2a may be about 5° to about 45°.

An angle between a straight line connecting an inner circumference of the first scattering pattern SP1 and the edge of the flat portion FA of the pixel electrode 171 to each other at the longest distance and the third direction (Z-axis direction) may be a second inner circumference angle θ2b. The second inner circumference angle θ2b may be substantially the same as the second outer circumference angle θ2a.

In FIG. 8, the first scattering pattern SP1 and the first emission area EA1 corresponding to the first scattering pattern SP1 have been described by way of example. The second scattering pattern SP2, the third scattering pattern SP3, and the fourth scattering pattern SP4 may be formed in the same manner as the first scattering pattern SP1.

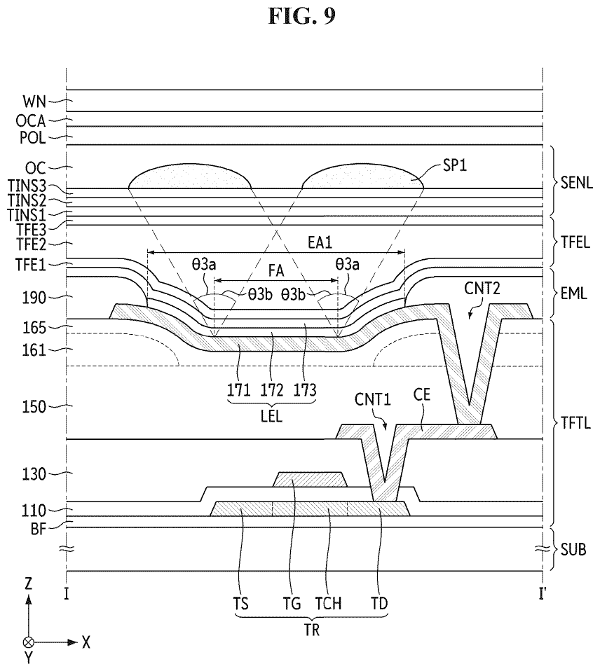

FIG. 9 is a cross-sectional view illustrating still another example taken along the line I-I′ of FIG. 6. A description of contents overlapping the contents described above will be omitted or briefly provided, and contents different from the contents described above will be mainly described.

Referring to FIG. 9, the display panel 100 may include a substrate SUB, a thin film transistor layer TFTL, a light-emitting element layer EML, an encapsulation layer TFEL, a touch-sensing layer SENL, a polarizing member POL, an adhesive member OCA, and a window member WN.

In comparison with FIG. 8, which depicts the first scattering pattern SP1 located between the second touch-insulating film TINS2 and the third touch-insulating film TINS3, FIG. 9 instead shows the first scattering pattern SP1 between the third touch-insulating film TINS3 and the overcoat OC. For example, a flat portion of the first scattering pattern SP1 may be in contact with the third touch-insulating film TINS3, and a convex portion of the first scattering pattern SP1 may be in contact with the overcoat OC.

An angle between a straight line connecting an outer circumference of the first scattering pattern SP1 and an edge of the flat portion FA of the pixel electrode 171 to each other at the shortest distance and the third direction (Z-axis direction) may be a third outer circumference angle θ3a. As an example, the third outer circumference angle θ3a may be about 5° to about 45°.

An angle between a straight line connecting an inner circumference of the first scattering pattern SP1 and the edge of the flat portion FA of the pixel electrode 171 to each other at the longest distance and the third direction (Z-axis direction) may be a third inner circumference angle θ3b. The third inner circumference angle θ3b may be substantially the same as the third outer circumference angle θ3a.

In FIG. 9, the first scattering pattern SP1 and the first emission area EA1 corresponding to the first scattering pattern SP1 have been described by way of example. The second scattering pattern SP2, the third scattering pattern SP3, and the fourth scattering pattern SP4 may be formed in the same manner as the first scattering pattern SP1.

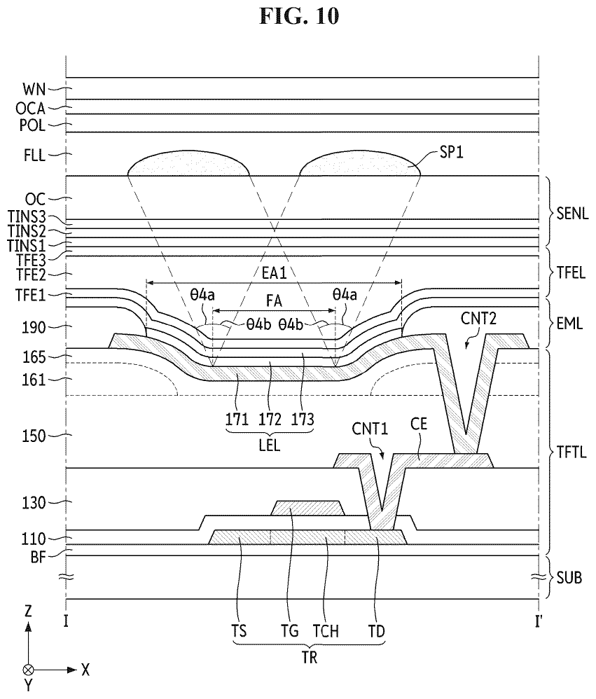

FIG. 10 is a cross-sectional view illustrating still another example taken along the line I-I′ of FIG. 6. A description of contents overlapping the contents described above will be omitted or briefly provided, and contents different from the contents described above will be mainly described.

Referring to FIG. 10, the display panel 100 may include a substrate SUB, a thin film transistor layer TFTL, a light-emitting element layer EML, an encapsulation layer TFEL, a touch-sensing layer SENL, a planarization layer FLL, a polarizing member POL, an adhesive member OCA, and a window member WN.

The planarization layer FLL may planarize a step caused by the scattering patterns SP1 to SP4. The planarization layer FLL may be made of an acrylic resin, an epoxy resin, a phenolic resin, a polyamide resin, or a polyimide resin, but is not limited thereto.

In comparison with FIG. 9, which shows the first scattering pattern SP1 between the third touch-insulating film TINS3 and the overcoat OC, FIG. 10 shows the first scattering pattern SP1 between the overcoat OC and the planarization layer FLL. For example, a flat portion of the first scattering pattern SP1 may be in contact with the overcoat OC, and a convex portion of the first scattering pattern SP1 may be in contact with the planarization layer FLL.

An angle between a straight line connecting an outer circumference of the first scattering pattern SP1 and an edge of the flat portion FA of the pixel electrode 171 to each other at the shortest distance and the third direction (Z-axis direction) may be a fourth outer circumference angle θ4a. As an example, the fourth outer circumference angle θ4a may be about 5° to about 45°.

An angle between a straight line connecting an inner circumference of the first scattering pattern SP1 and the edge of the flat portion FA of the pixel electrode 171 to each other at the longest distance and the third direction (Z-axis direction) may be a fourth inner circumference angle θ4b. The fourth inner circumference angle θ4b may be substantially the same as the fourth outer circumference angle θ4a.

In FIG. 10, the first scattering pattern SP1 and the first emission area EA1 corresponding to the first scattering pattern SP1 have been described by way of example. The second scattering pattern SP2, the third scattering pattern SP3, and the fourth scattering pattern SP4 may be formed in the same manner as the first scattering pattern SP1.

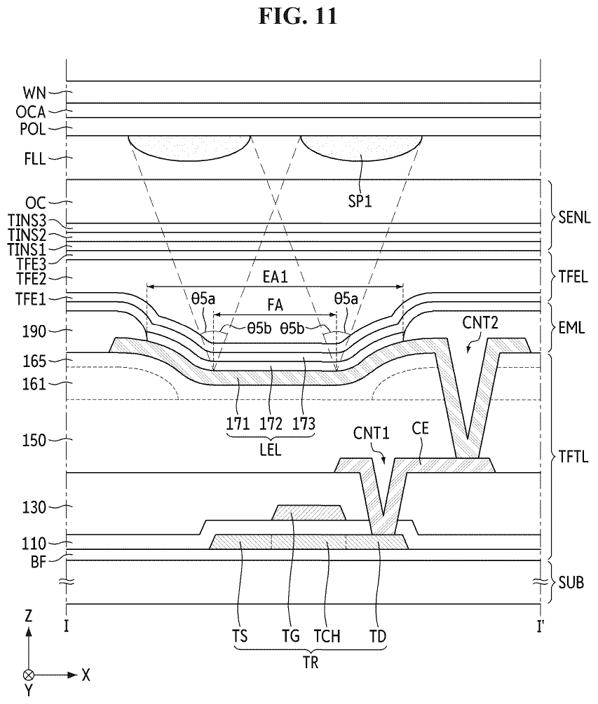

FIG. 11 is a cross-sectional view illustrating still another example taken along the line I-I′ of FIG. 6. A description of contents overlapping the contents described above will be omitted or briefly provided, and contents different from the contents described above will be mainly described.

Referring to FIG. 11, the display panel 100 may include a substrate SUB, a thin film transistor layer TFTL, a light-emitting element layer EML, an encapsulation layer TFEL, a touch-sensing layer SENL, a planarization layer FLL, a polarizing member POL, an adhesive member OCA, and a window member WN.

In comparison with FIG. 10, which shows the first scattering pattern SP1 between the overcoat OC and the planarization layer FLL, FIG. 11 shows the first scattering pattern SP1 between the planarization layer FLL and the polarizing member POL. For example, a flat portion of the first scattering pattern SP1 may be in contact with a lower surface of the polarizing member POL, and a convex portion of the first scattering pattern SP1 may be in contact with the planarization layer FLL.

An angle between a straight line connecting an outer circumference of the first scattering pattern SP1 and an edge of the flat portion FA of the pixel electrode 171 to each other at the shortest distance and the third direction (Z-axis direction) may be a fifth outer circumference angle θ5a. As an example, the fifth outer circumference angle θ5a may be about 5° to about 45°.

An angle between a straight line connecting an inner circumference of the first scattering pattern SP1 and the edge of the flat portion FA of the pixel electrode 171 to each other at the longest distance and the third direction (Z-axis direction) may be a fifth inner circumference angle θ5b. The fifth inner circumference angle θ5b may be substantially the same as the fifth outer circumference angle θ5a.

In FIG. 11, the first scattering pattern SP1 and the first emission area EA1 corresponding to the first scattering pattern SP1 have been described by way of example. The second scattering pattern SP2, the third scattering pattern SP3, and the fourth scattering pattern SP4 may be formed in the same manner as the first scattering pattern SP1.

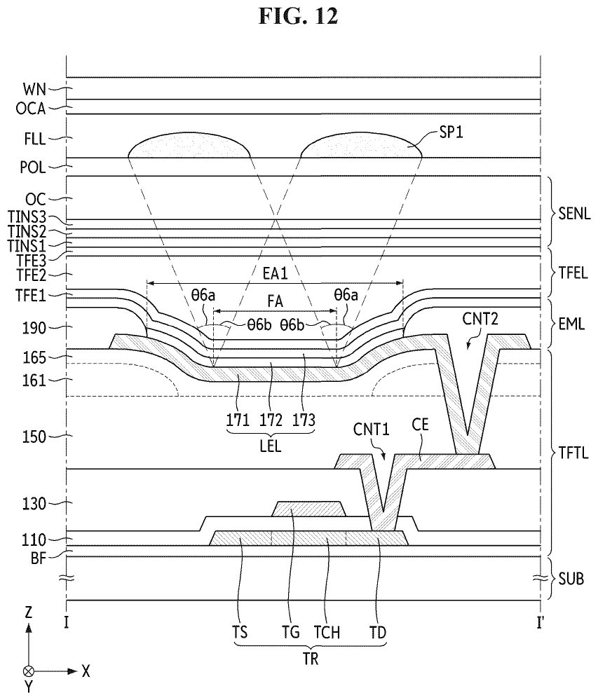

FIG. 12 is a cross-sectional view illustrating still another example taken along the line I-I′ of FIG. 6. A description of contents overlapping the contents described above will be omitted or briefly provided, and contents different from the contents described above will be mainly described.

Referring to FIG. 12, the display panel 100 may include a substrate SUB, a thin film transistor layer TFTL, a light-emitting element layer EML, an encapsulation layer TFEL, a touch-sensing layer SENL, a polarizing member POL, a planarization layer FLL, an adhesive member OCA, and a window member WN.

In comparison with FIG. 11, which shows the first scattering pattern SP1 between the planarization layer FLL and the polarizing member POL, FIG. 12 shows the first scattering pattern SP1 between the polarizing member POL and the planarization layer FLL in FIG. 12. For example, a flat portion of the first scattering pattern SP1 may be in contact with an upper surface of the polarizing member POL, and a convex portion of the first scattering pattern SP1 may be in contact with the planarization layer FLL.

An angle between a straight line connecting an outer circumference of the first scattering pattern SP1 and an edge of the flat portion FA of the pixel electrode 171 to each other at the shortest distance and the third direction (Z-axis direction) may be a sixth outer circumference angle θ6a. As an example, the sixth outer circumference angle θ6a may be about 5° to about 45°.

An angle between a straight line connecting an inner circumference of the first scattering pattern SP1 and the edge of the flat portion FA of the pixel electrode 171 to each other at the longest distance and the third direction (Z-axis direction) may be a sixth inner circumference angle θ6b. The sixth inner circumference angle θ6b may be substantially the same as the sixth outer circumference angle θ6a.

In FIG. 12, the first scattering pattern SP1 and the first emission area EA1 corresponding to the first scattering pattern SP1 have been described by way of example. The second scattering pattern SP2, the third scattering pattern SP3, and the fourth scattering pattern SP4 may be formed in the same manner as the first scattering pattern SP1.

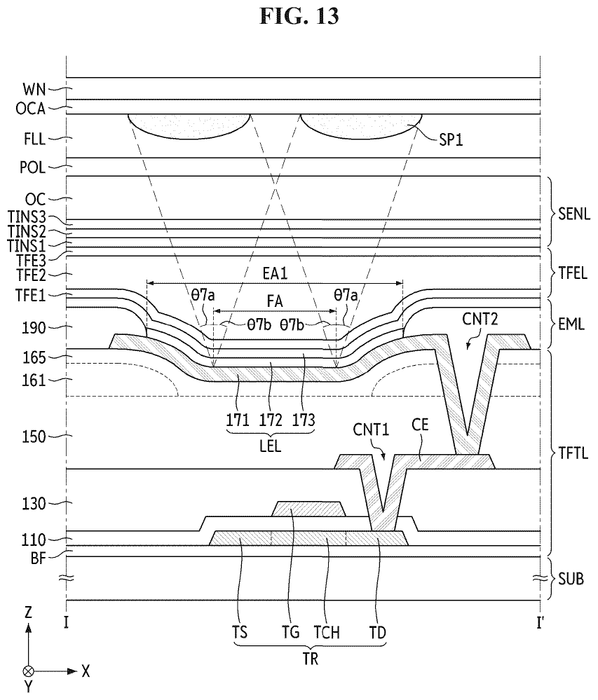

FIG. 13 is a cross-sectional view illustrating still another example taken along the line I-I′ of FIG. 6. A description of contents overlapping the contents described above will be omitted or briefly provided, and contents different from the contents described above will be mainly described.

Referring to FIG. 13, the display panel 100 may include a substrate SUB, a thin film transistor layer TFTL, a light-emitting element layer EML, an encapsulation layer TFEL, a touch-sensing layer SENL, a polarizing member POL, a planarization layer FLL, an adhesive member OCA, and a window member WN.

In comparison with FIG. 12, which shows the first scattering pattern SP1 between the polarizing member POL and the planarization layer FLL, FIG. 13 shows the first scattering pattern SP1 between the planarization layer FLL and the adhesive member OCA in FIG. 13. For example, a flat portion of the first scattering pattern SP1 may be in contact with a lower surface of the adhesive member OCA, and a convex portion of the first scattering pattern SP1 may be in contact with the planarization layer FLL.

An angle between a straight line connecting an outer circumference of the first scattering pattern SP1 and an edge of the flat portion FA of the pixel electrode 171 to each other at the shortest distance and the third direction (Z-axis direction) may be a seventh outer circumference angle θ7a. As an example, the seventh outer circumference angle θ7a may be about 5° to about 45°.

An angle between a straight line connecting an inner circumference of the first scattering pattern SP1 and the edge of the flat portion FA of the pixel electrode 171 to each other at the longest distance and the third direction (Z-axis direction) may be a seventh inner circumference angle θ7b. The seventh inner circumference angle θ7b may be substantially the same as the seventh outer circumference angle θ7a.

In FIG. 13, the first scattering pattern SP1 and the first emission area EA1 corresponding to the first scattering pattern SP1 have been described by way of example. The second scattering pattern SP2, the third scattering pattern SP3, and the fourth scattering pattern SP4 may be formed in the same manner as the first scattering pattern SP1.

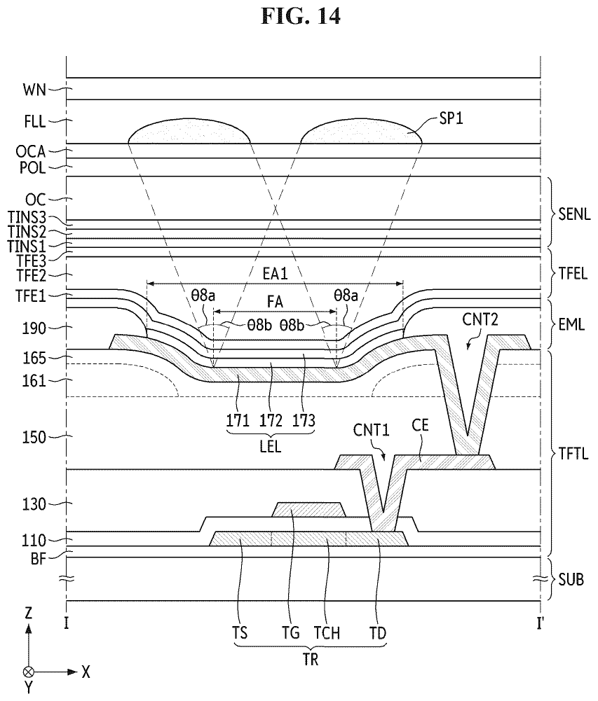

FIG. 14 is a cross-sectional view illustrating still another example taken along the line I-I′ of FIG. 6. A description of contents overlapping the contents described above will be omitted or briefly provided, and contents different from the contents described above will be mainly described.

Referring to FIG. 14, the display panel 100 may include a substrate SUB, a thin film transistor layer TFTL, a light-emitting element layer EML, an encapsulation layer TFEL, a touch-sensing layer SENL, a polarizing member POL, an adhesive member OCA, a planarization layer FLL, and a window member WN.

In comparison with FIG. 13, which shows the first scattering pattern SP1 between the planarization layer FLL and the adhesive member OCA, FIG. 14 shows the first scattering pattern SP1 between the adhesive member OCA and the planarization layer FLL in FIG. 14. For example, a flat portion of the first scattering pattern SP1 may be in contact with an upper surface of the adhesive member OCA, and a convex portion of the first scattering pattern SP1 may be in contact with the planarization layer FLL.

An angle between a straight line connecting an outer circumference of the first scattering pattern SP1 and an edge of the flat portion FA of the pixel electrode 171 to each other at the shortest distance and the third direction (Z-axis direction) may be an eighth outer circumference angle θ8a. As an example, the eighth outer circumference angle θ8a may be about 5° to about 45°.

An angle between a straight line connecting an inner circumference of the first scattering pattern SP1 and the edge of the flat portion FA of the pixel electrode 171 to each other at the longest distance and the third direction (Z-axis direction) may be an eighth inner circumference angle θ8b. The eighth inner circumference angle θ8b may be substantially the same as the eighth outer circumference angle θ8a.

In FIG. 14, the first scattering pattern SP1 and the first emission area EA1 corresponding to the first scattering pattern SP1 have been described by way of example. The second scattering pattern SP2, the third scattering pattern SP3, and the fourth scattering pattern SP4 may be formed in the same manner as the first scattering pattern SP1.

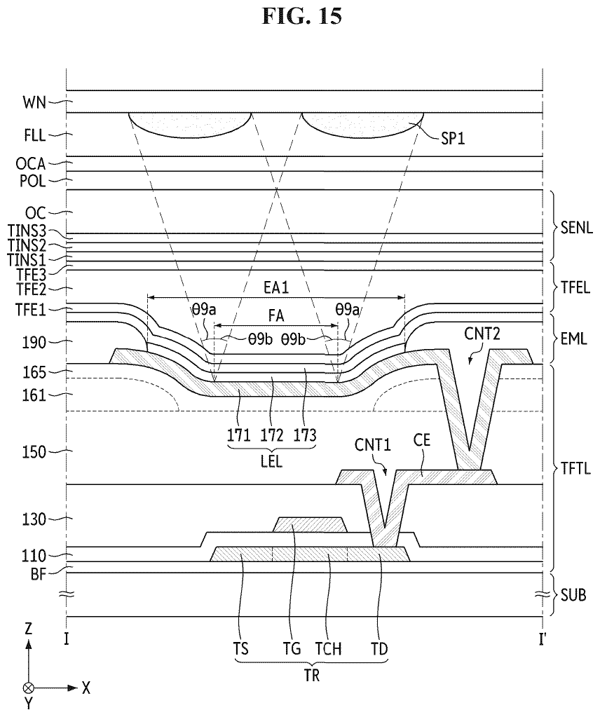

FIG. 15 is a cross-sectional view illustrating still another example taken along the line I-I′ of FIG. 6. A description of contents overlapping the contents described above will be omitted or briefly provided, and contents different from the contents described above will be mainly described.

Referring to FIG. 15, the display panel 100 may include a substrate SUB, a thin film transistor layer TFTL, a light-emitting element layer EML, an encapsulation layer TFEL, a touch-sensing layer SENL, a polarizing member POL, an adhesive member OCA, a planarization layer FLL, and a window member WN.

In comparison with FIG. 14, which shows the first scattering pattern SP1 between the adhesive member OCA and the planarization layer FLL, FIG. 15 shows the first scattering pattern SP1 between the planarization layer FLL and the window member WN in FIG. 15. For example, a flat portion of the first scattering pattern SP1 may be in contact with a lower surface of the window member WN, and a convex portion of the first scattering pattern SP1 may be in contact with the planarization layer FLL.

An angle between a straight line connecting an outer circumference of the first scattering pattern SP1 and an edge of the flat portion FA of the pixel electrode 171 to each other at the shortest distance and the third direction (Z-axis direction) may be a ninth outer circumference angle θ9a. As an example, the ninth outer circumference angle θ9a may be about 5° to about 45°.

An angle between a straight line connecting an inner circumference of the first scattering pattern SP1 and the edge of the flat portion FA of the pixel electrode 171 to each other at the longest distance and the third direction (Z-axis direction) may be a ninth inner circumference angle θ9b. The ninth inner circumference angle θ9b may be substantially the same as the ninth outer circumference angle θ9a.

In FIG. 15, the first scattering pattern SP1 and the first emission area EA1 corresponding to the first scattering pattern SP1 have been described by way of example. The second scattering pattern SP2, the third scattering pattern SP3, and the fourth scattering pattern SP4 may be formed in the same manner as the first scattering pattern SP1.

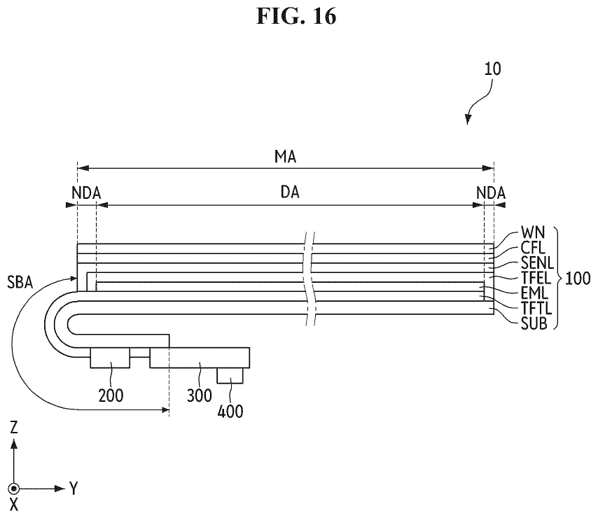

FIG. 16 is a side view of a display device according to some embodiments of the present disclosure. A description of contents overlapping the contents described above will be omitted or briefly provided, and contents different from the contents described above will be mainly described.

Referring to FIG. 16, the display panel 100 may include a substrate SUB, a thin film transistor layer TFTL, a light-emitting element layer EML, an encapsulation layer TFEL, a touch-sensing layer SENL, a color filter layer CFL, and a window member WN.

The thin film transistor layer TFTL may be located on the substrate SUB, and the light-emitting element layer EML may be located on the thin film transistor layer TFTL. The encapsulation layer TFEL may be located on the light-emitting element layer EML, and the touch-sensing layer SENL may be located on the encapsulation layer TFEL. The color filter layer CFL may be located on the touch-sensing layer SENL, and the window member WN may be located on the color filter layer CFL.

The color filter layer CFL may be located in the display area DA and the non-display area NDA of the main area MA. The color filter layer CFL may include a plurality of color filters. Each color filter may transmit only light of a corresponding color, and may block other light.

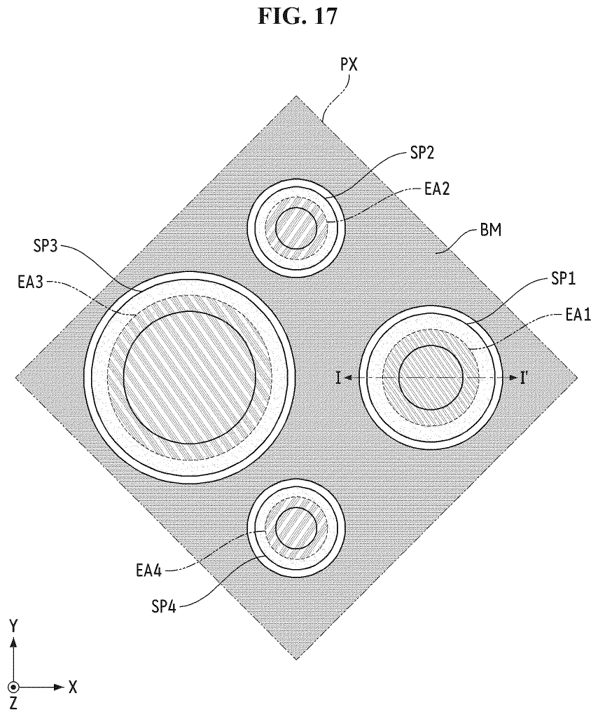

FIG. 17 is a layout diagram illustrating an example of the display device of FIG. 16. A description of contents overlapping the contents described above will be omitted, and contents different from the contents described above will be mainly described.

The pixel PX may include a first emission area EA1, a second emission area EA2, a third emission area EA3, a fourth emission area EA4, a first scattering pattern SP1, a second scattering pattern SP2, a third scattering pattern SP3, a fourth scattering pattern SP4, and a black matrix BM.

The black matrix BM may be spaced apart from the first emission area EA1, the second emission area EA2, the third emission area EA3, and the fourth emission area EA4. The black matrix BM may be spaced apart from the first scattering pattern SP1, the second scattering pattern SP2, the third scattering pattern SP3, and the fourth scattering pattern SP4. The black matrix BM may be formed using a material for absorbing visible light, such as a metal material or a resin material including a pigment or a dye. The black matrix BM may reduce or prevent visibility of electrodes and lines of the display panel 100 from the outside.

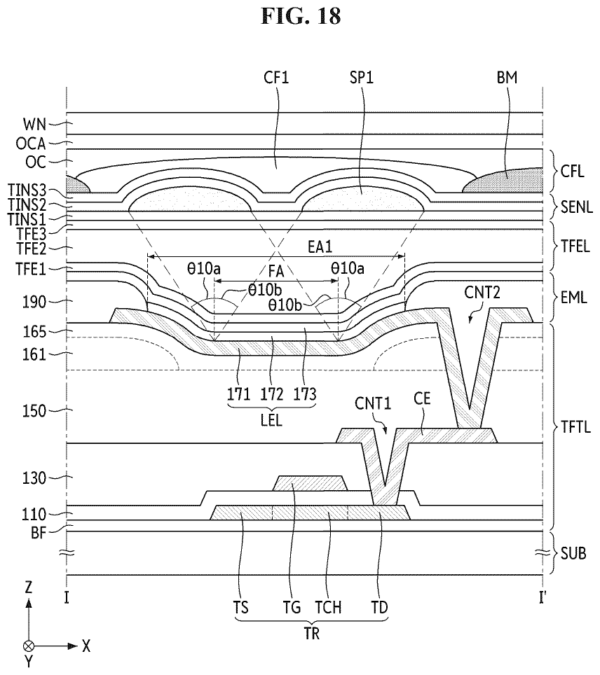

FIG. 18 is a cross-sectional view illustrating an example taken along the line I-I′ of FIG. 17. A description of contents overlapping the contents described above will be omitted or briefly provided, and contents different from the contents described above will be mainly described.

Referring to FIG. 18, the display panel 100 may include a substrate SUB, a thin film transistor layer TFTL, a light-emitting element layer EML, an encapsulation layer TFEL, a touch-sensing layer SENL, a color filter layer CFL, an adhesive member OCA, and a window member WN.

In FIG. 18, the first scattering pattern SP1 and the first emission area EA1 corresponding to the first scattering pattern SP1 will be described by way of example. The second scattering pattern SP2, the third scattering pattern SP3, and the fourth scattering pattern SP4 may be formed in the same manner as the first scattering pattern SP1.

The color filter layer CFL may be located between the touch-sensing layer SENL and the adhesive member OCA. The color filter layer CFL may include a first color filter CF1, a second color filter CF2, a third color filter CF3, a black matrix BM, and an overcoat OC.

The black matrix BM may overlap the pixel-defining film 190 in the third direction (Z-axis direction). The black matrix BM may not overlap (e.g., may be spaced from in plan view) the emission areas EA1 to EA4 in the third direction (Z-axis direction). The black matrix BM may not overlap the scattering patterns SP1 to SP4 in the third direction (Z-axis direction).

The overcoat OC may be located on the black matrix BM and the color filters CF1 to CF3. The overcoat OC may planarize a step caused by the black matrix BM and the color filters CF1 to CF3.

The first color filter CF1 may transmit the light of the first color and block other light. The first color filter CF1 may overlap the first emission area EA1 emitting the light of the first color in the third direction (Z-axis direction). Accordingly, the light of the first color emitted from the first emission area EA1 may be transmitted through the first color filter CF1 and travel in the third direction (Z-axis direction).

The first color filter CF1 may overlap the first scattering pattern SP1 in the third direction (Z-axis direction). An outer circumference of the first color filter CF1 may be greater than an outer circumference of the first scattering pattern SP1.

The second color filter CF2 may transmit the light of the second color and may block other light. The second color filter CF2 may overlap the second emission area EA2 and the fourth emission area EA4 that emit the light of the second color in the third direction (Z-axis direction). Accordingly, the light of the second color emitted from the second emission area EA2 and the fourth emission area EA4 may be transmitted through the second color filter CF2 and travel in the third direction (Z-axis direction).

The second color filter CF2 may overlap the second scattering pattern SP2 or the fourth scattering pattern SP4 in the third direction (Z-axis direction). An outer circumference of the second color filter CF2 may be greater than respective outer circumferences of the second scattering pattern SP2 and the fourth scattering pattern SP4.

The third color filter CF3 may transmit the light of the third color and may block other light. The third color filter CF3 may overlap the third emission area EA3 emitting the light of the third color in the third direction (Z-axis direction). Accordingly, the light of the third color emitted from the third emission area EA3 may be transmitted through the third color filter CF3 and travel in the third direction (Z-axis direction).

The third color filter CF3 may overlap the third scattering pattern SP3 in the third direction (Z-axis direction). An outer circumference of the third color filter CF3 may be greater than an outer circumference of the third scattering pattern SP3.

Each of the color filters CF1 to CF3 of the color filter layer CFL may transmit only light of a corresponding wavelength. Accordingly, the color filter layer CFL may reduce a reflection amount of light incident from the outside onto the display device 10, similar to the polarizing member POL. Accordingly, it is possible to reduce or prevent light incident from the outside onto the display device 10 being reflected and viewed by a user.

An angle between a straight line connecting the outer circumference of the first scattering pattern SP1 and an edge of the flat portion FA of the pixel electrode 171 to each other at the shortest distance and the third direction (Z-axis direction) may be a tenth outer circumference angle θ10a. As an example, the tenth outer circumference angle θ10a may be about 5° to about 45°.

An angle between a straight line connecting an inner circumference of the first scattering pattern SP1 and the edge of the flat portion FA of the pixel electrode 171 to each other at the longest distance and the third direction (Z-axis direction) may be a tenth inner circumference angle θ10b. The tenth inner circumference angle θ10b may be substantially the same as the tenth outer circumference angle θ10a.

In FIG. 18, the first scattering pattern SP1 and the first emission area EA1 corresponding to the first scattering pattern SP1 have been described by way of example. The second scattering pattern SP2, the third scattering pattern SP3, and the fourth scattering pattern SP4 may be formed in the same manner as the first scattering pattern SP1.

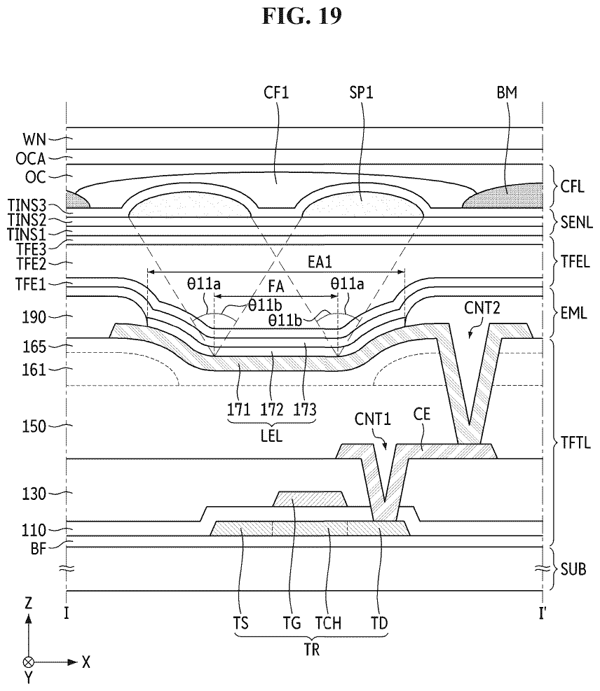

FIG. 19 is a cross-sectional view illustrating another example taken along the line I-I′ of FIG. 17. A description of contents overlapping the contents described above will be omitted or briefly provided, and contents different from the contents described above will be mainly described.

Referring to FIG. 19, the display panel 100 may include a substrate SUB, a thin film transistor layer TFTL, a light-emitting element layer EML, an encapsulation layer TFEL, a touch-sensing layer SENL, a color filter layer CFL, an adhesive member OCA, and a window member WN.

In comparison with FIG. 18, which shows the first scattering pattern SP1 between the first touch-insulating film TINS1 and the second touch-insulating film TINS2, FIG. 19 shows the first scattering pattern SP1 between the second touch-insulating film TINS2 and the third touch-insulating film TINS3. For example, a flat portion of the first scattering pattern SP1 may be in contact with the second touch-insulating film TINS2, and a convex portion of the first scattering pattern SP1 may be in contact with the third touch-insulating film TINS3.

An angle between a straight line connecting an outer circumference of the first scattering pattern SP1 and an edge of the flat portion FA of the pixel electrode 171 to each other at the shortest distance and the third direction (Z-axis direction) may be an eleventh outer circumference angle θ11a. As an example, the eleventh outer circumference angle θ11a may be about 5° to about 45°.

An angle between a straight line connecting an inner circumference of the first scattering pattern SP1 and the edge of the flat portion FA of the pixel electrode 171 to each other at the longest distance and the third direction (Z-axis direction) may be an eleventh inner circumference angle θ11b. The eleventh inner circumference angle θ11b may be substantially the same as the eleventh outer circumference angle θ11a.

In FIG. 19, the first scattering pattern SP1 and the first emission area EA1 corresponding to the first scattering pattern SP1 have been described by way of example. The second scattering pattern SP2, the third scattering pattern SP3, and the fourth scattering pattern SP4 may be formed in the same manner as the first scattering pattern SP1.

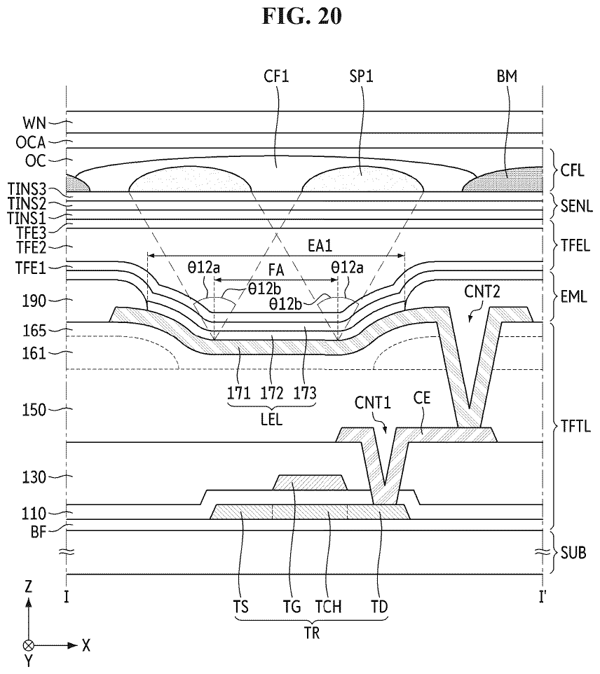

FIG. 20 is a cross-sectional view illustrating still another example taken along the line I-I′ of FIG. 17. A description of contents overlapping the contents described above will be omitted or briefly provided, and contents different from the contents described above will be mainly described.

Referring to FIG. 20, the display panel 100 may include a substrate SUB, a thin film transistor layer TFTL, a light-emitting element layer EML, an encapsulation layer TFEL, a touch-sensing layer SENL, a color filter layer CFL, an adhesive member OCA, and a window member WN.

In comparison with FIG. 19, which shows the first scattering pattern SP1 between the second touch-insulating film TINS2 and the third touch-insulating film TINS3, FIG. 20 shows the first scattering pattern SP1 between the third touch-insulating film TINS3 and the first color filter CF1 in FIG. 20. For example, a flat portion of the first scattering pattern SP1 may be in contact with the third touch-insulating film TINS3, and a convex portion of the first scattering pattern SP1 may be in contact with the first color filter CF1.

An angle between a straight line connecting an outer circumference of the first scattering pattern SP1 and an edge of the flat portion FA of the pixel electrode 171 to each other at the shortest distance and the third direction (Z-axis direction) may be a twelfth outer circumference angle θ12a. As an example, the twelfth outer circumference angle θ12a may be about 5° to about 45°.

An angle between a straight line connecting an inner circumference of the first scattering pattern SP1 and the edge of the flat portion FA of the pixel electrode 171 to each other at the longest distance and the third direction (Z-axis direction) may be a twelfth inner circumference angle θ12b. The twelfth inner circumference angle θ12b may be substantially the same as the twelfth outer circumference angle θ12a.

In FIG. 20, the first scattering pattern SP1 and the first emission area EA1 corresponding to the first scattering pattern SP1 have been described by way of example. The second scattering pattern SP2, the third scattering pattern SP3, and the fourth scattering pattern SP4 may be formed in the same manner as the first scattering pattern SP1.

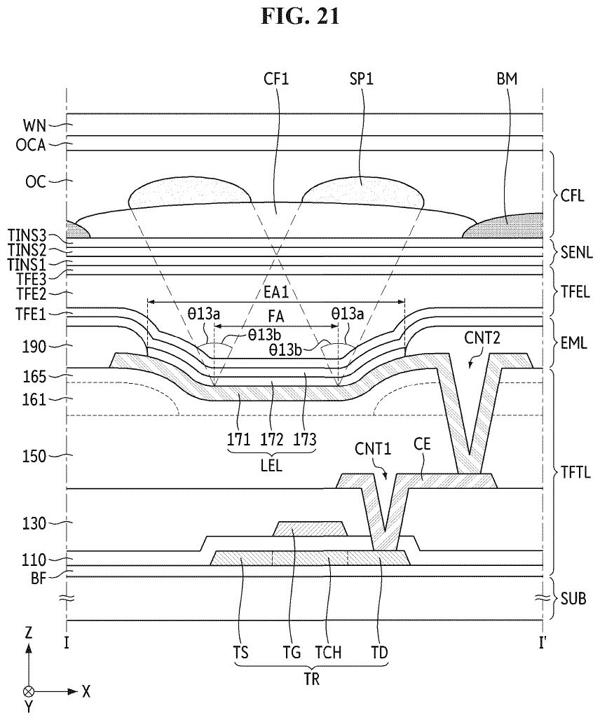

FIG. 21 is a cross-sectional view illustrating still another example taken along the line I-I′ of FIG. 17. A description of contents overlapping the contents described above will be omitted or briefly provided, and contents different from the contents described above will be mainly described.

Referring to FIG. 21, the display panel 100 may include a substrate SUB, a thin film transistor layer TFTL, a light-emitting element layer EML, an encapsulation layer TFEL, a touch-sensing layer SENL, a color filter layer CFL, an adhesive member OCA, and a window member WN.

In comparison with FIG. 20, which shows the first scattering pattern SP1 between the third touch-insulating film TINS3 and the first color filter CF1, FIG. 21 shows the first scattering pattern SP1 between the first color filter CF1 and the overcoat OC in FIG. 21. For example, a lower surface of the first scattering pattern SP1 may be in contact with the first color filter CF1, and an upper surface of the first scattering pattern SP1 may be in contact with the overcoat OC.

An angle between a straight line connecting an outer circumference of the first scattering pattern SP1 and an edge of the flat portion FA of the pixel electrode 171 to each other at the shortest distance and the third direction (Z-axis direction) may be a thirteenth outer circumference angle θ13a. As an example, the thirteenth outer circumference angle θ13a may be about 5° to about 45°.

An angle between a straight line connecting an inner circumference of the first scattering pattern SP1 and the edge of the flat portion FA of the pixel electrode 171 to each other at the longest distance and the third direction (Z-axis direction) may be a thirteenth inner circumference angle θ13b. The thirteenth inner circumference angle θ13b may be substantially the same as the thirteenth outer circumference angle θ13a.

In FIG. 21, the first scattering pattern SP1 and the first emission area EA1 corresponding to the first scattering pattern SP1 have been described by way of example. The second scattering pattern SP2, the third scattering pattern SP3, and the fourth scattering pattern SP4 may be formed in the same manner as the first scattering pattern SP1.

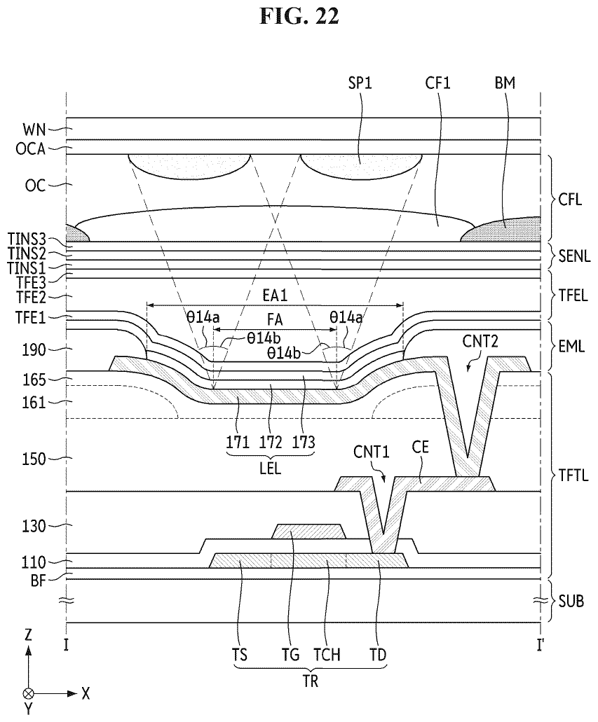

FIG. 22 is a cross-sectional view illustrating still another example taken along the line I-I′ of FIG. 17. A description of contents overlapping the contents described above will be omitted or briefly provided, and contents different from the contents described above will be mainly described.

Referring to FIG. 22, the display panel 100 may include a substrate SUB, a thin film transistor layer TFTL, a light-emitting element layer EML, an encapsulation layer TFEL, a touch-sensing layer SENL, a color filter layer CFL, an adhesive member OCA, and a window member WN.

In comparison with FIG. 21, which shows the first scattering pattern SP1 between the first color filter CF1 and the overcoat OC, FIG. 22 shows the first scattering pattern SP1 between the overcoat OC and the adhesive member OCA in FIG. 22. For example, a flat portion of the first scattering pattern SP1 may be in contact with a lower surface of the adhesive member OCA, and a convex portion of the first scattering pattern SP1 may be in contact with the overcoat OC.

An angle between a straight line connecting an outer circumference of the first scattering pattern SP1 and an edge of the flat portion FA of the pixel electrode 171 to each other at the shortest distance and the third direction (Z-axis direction) may be a fourteenth outer circumference angle θ14a. As an example, the fourteenth outer circumference angle θ14a may be about 5° to about 45°.

An angle between a straight line connecting an inner circumference of the first scattering pattern SP1 and the edge of the flat portion FA of the pixel electrode 171 to each other at the longest distance and the third direction (Z-axis direction) may be a fourteenth inner circumference angle θ14b. The fourteenth inner circumference angle θ14b may be substantially the same as the fourteenth outer circumference angle θ14a.

In FIG. 22, the first scattering pattern SP1 and the first emission area EA1 corresponding to the first scattering pattern SP1 have been described by way of example. The second scattering pattern SP2, the third scattering pattern SP3, and the fourth scattering pattern SP4 may be formed in the same manner as the first scattering pattern SP1.

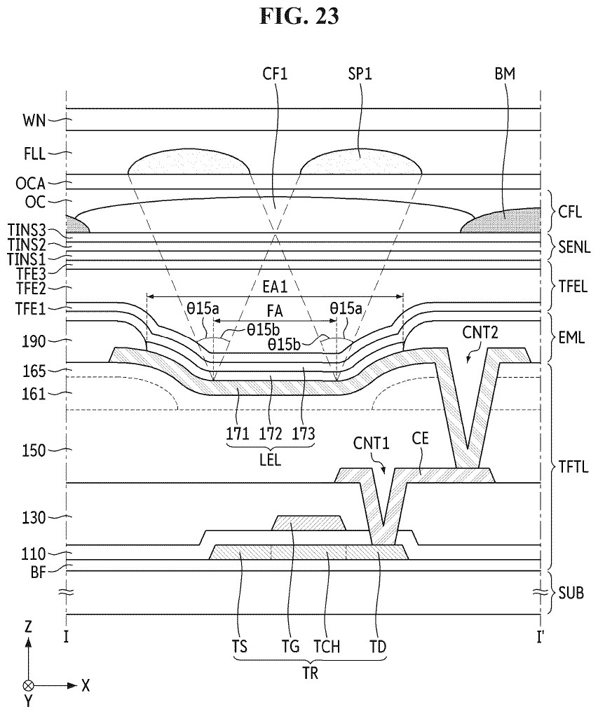

FIG. 23 is a cross-sectional view illustrating still another example taken along the line I-I′ of FIG. 17. A description of contents overlapping the contents described above will be omitted or briefly provided, and contents different from the contents described above will be mainly described.

Referring to FIG. 23, the display panel 100 may include a substrate SUB, a thin film transistor layer TFTL, a light-emitting element layer EML, an encapsulation layer TFEL, a touch-sensing layer SENL, a color filter layer CFL, an adhesive member OCA, a planarization layer FLL, and a window member WN.

The planarization layer FLL may be located on the adhesive member OCA and the first scattering pattern SP1. The planarization layer FLL may planarize a step caused by the first scattering pattern SP1.

In comparison with FIG. 22, which shows the first scattering pattern SP1 between the overcoat OC and the adhesive member OCA, FIG. 23 shows the first scattering pattern SP1 between the adhesive member OCA and the planarization layer FLL in FIG. 23. For example, a flat portion of the first scattering pattern SP1 may be in contact with an upper surface of the adhesive member OCA, and a convex portion of the first scattering pattern SP1 may be in contact with the planarization layer FLL.

An angle between a straight line connecting an outer circumference of the first scattering pattern SP1 and an edge of the flat portion FA of the pixel electrode 171 to each other at the shortest distance and the third direction (Z-axis direction) may be a fifteenth outer circumference angle θ15a. As an example, the fifteenth outer circumference angle θ15a may be about 5° to about 45°.

An angle between a straight line connecting an inner circumference of the first scattering pattern SP1 and the edge of the flat portion FA of the pixel electrode 171 to each other at the longest distance and the third direction (Z-axis direction) may be a fifteenth inner circumference angle θ16b. The fifteenth inner circumference angle θ16b may be substantially the same as the fifteenth outer circumference angle θ15a.

In FIG. 23, the first scattering pattern SP1 and the first emission area EA1 corresponding to the first scattering pattern SP1 have been described by way of example. The second scattering pattern SP2, the third scattering pattern SP3, and the fourth scattering pattern SP4 may be formed in the same manner as the first scattering pattern SP1.

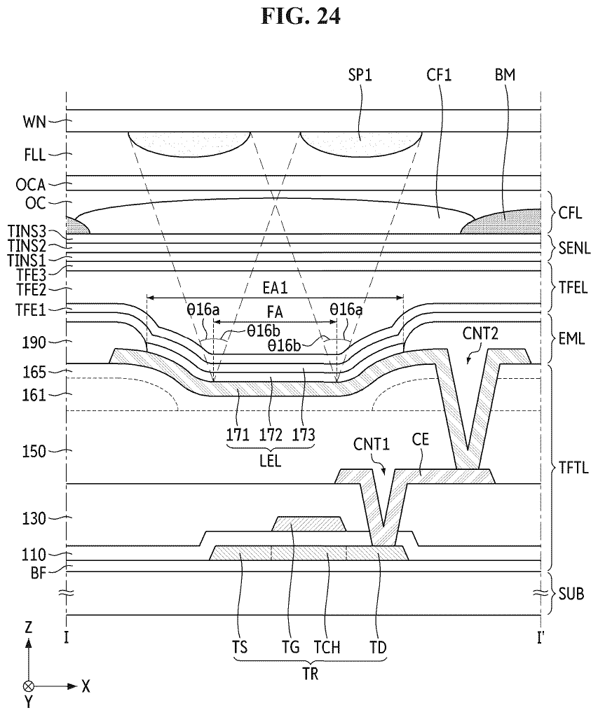

FIG. 24 is a cross-sectional view illustrating still another example taken along the line I-I′ of FIG. 17. A description of contents overlapping the contents described above will be omitted or briefly provided, and contents different from the contents described above will be mainly described.

Referring to FIG. 24, the display panel 100 may include a substrate SUB, a thin film transistor layer TFTL, a light-emitting element layer EML, an encapsulation layer TFEL, a touch-sensing layer SENL, a color filter layer CFL, an adhesive member OCA, a planarization layer FLL, and a window member WN.

In comparison with FIG. 23, which shows the first scattering pattern SP1 between the adhesive member OCA and the planarization layer FLL, FIG. 24 shows the first scattering pattern SP1 between the planarization layer FLL and the window member WN in FIG. 24. For example, a flat portion of the first scattering pattern SP1 may be in contact with a lower surface of the window member WN, and a convex portion of the first scattering pattern SP1 may be in contact with the planarization layer FLL.

An angle between a straight line connecting an outer circumference of the first scattering pattern SP1 and an edge of the flat portion FA of the pixel electrode 171 to each other at the shortest distance and the third direction (Z-axis direction) may be a sixteenth outer circumference angle θ16a. As an example, the sixteenth outer circumference angle θ16a may be about 5° to about 45°.

An angle between a straight line connecting an inner circumference of the first scattering pattern SP1 and the edge of the flat portion FA of the pixel electrode 171 to each other at the longest distance and the third direction (Z-axis direction) may be a sixteenth inner circumference angle θ16b. The sixteenth inner circumference angle θ16b may be substantially the same as the sixteenth outer circumference angle θ16a.

In FIG. 24, the first scattering pattern SP1 and the first emission area EA1 corresponding to the first scattering pattern SP1 have been described by way of example. The second scattering pattern SP2, the third scattering pattern SP3, and the fourth scattering pattern SP4 may be formed in the same manner as the first scattering pattern SP1.

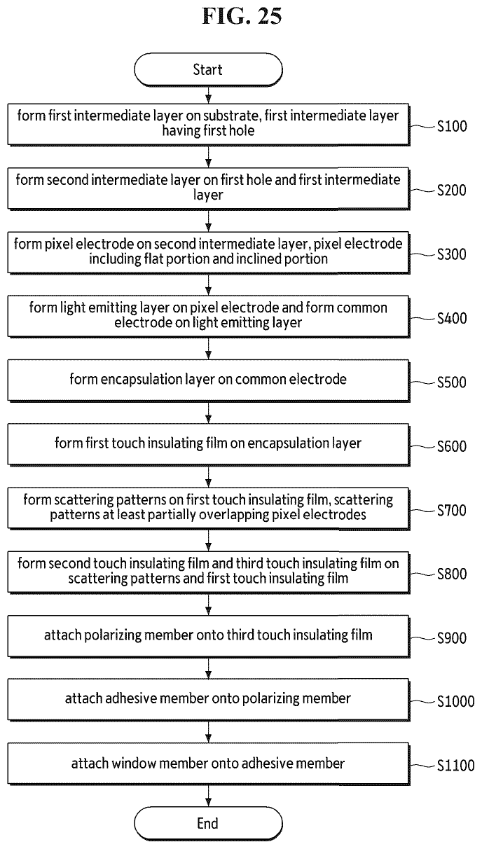

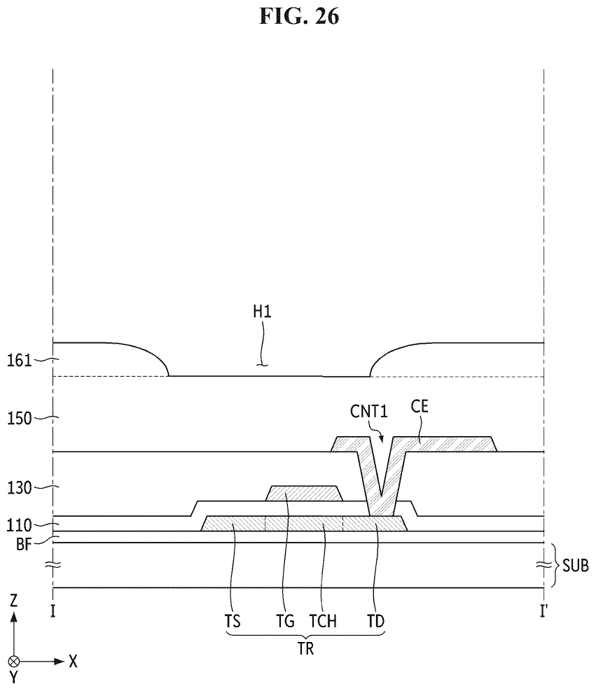

FIG. 25 is a flowchart for describing a manufacturing method of a display device according to some embodiments of the present disclosure. FIGS. 26 to 38 are cross-sectional views for describing respective processes of the manufacturing method of a display device of FIG. 25.

The first intermediate layer 161 having, or defining, a first hole H1 is formed on the substrate SUB (S100 of FIG. 25).

Referring to FIG. 26, the first intermediate layer 161 may be located on the protective film 150. The first intermediate layer 161 may include the first hole H1. The first intermediate layer 161 may be an organic film.

Subsequently, the second intermediate layer 165 is formed on the first hole H1 and the first intermediate layer 161 (S200 of FIG. 25).

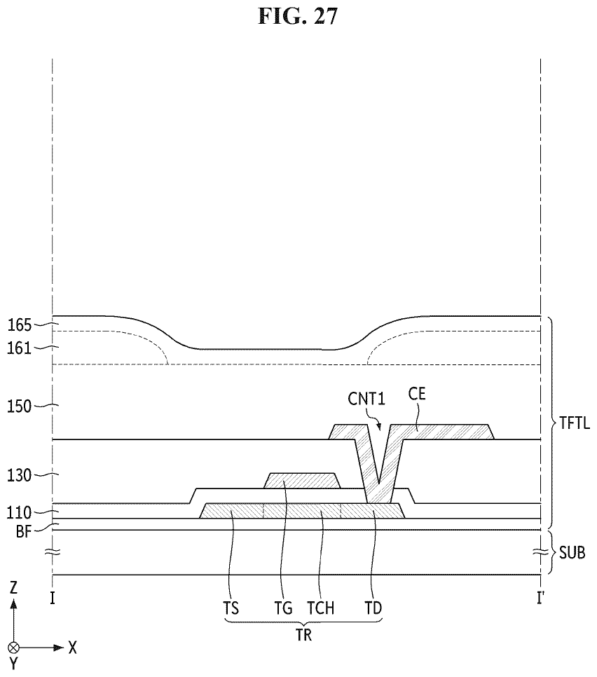

Referring to FIG. 27, the second intermediate layer 165 may be formed on the first intermediate layer 161. The second intermediate layer 165 is an organic film having viscosity, and may also be formed on the first hole H1. The second intermediate layer 165 may have a gentle inclination on the first hole H1.

Subsequently, the pixel electrode 171 including the flat portion FA and the inclined portion SA is formed on the second intermediate layer 165 (S300 of FIG. 25).

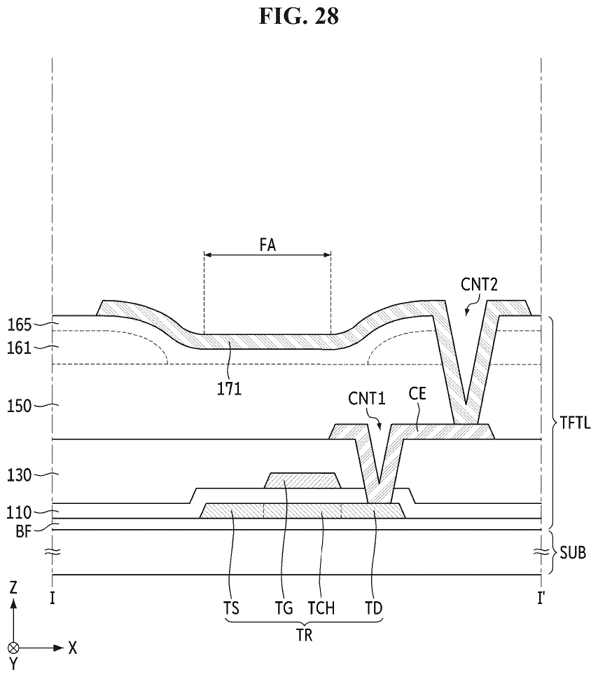

Referring to FIG. 28, the pixel electrode 171 may be formed on the second intermediate layer 165. The pixel electrode 171 may include the flat portion FA, which is a portion parallel, or substantially parallel, to the substrate SUB.

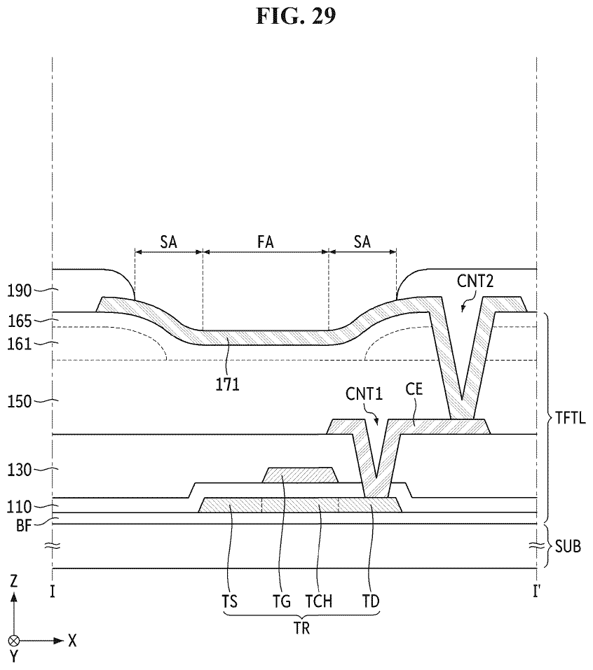

Referring to FIG. 29, the pixel-defining film 190 may be located on the second intermediate layer 165 and the pixel electrode 171. The pixel-defining film 190 may expose a portion of the pixel electrode 171 and may define the emission areas EA1 to EA4. The pixel electrode 171 may include the inclined portion SA located around the flat portion FA. The inclined portion SA may be a portion of the pixel electrode 171 formed in a direction crossing the substrate SUB around the flat portion FA.

Subsequently, the light-emitting layer 172 is formed on the pixel electrode 171, and the common electrode 173 is formed on the light-emitting layer 172 (S400 of FIG. 25).

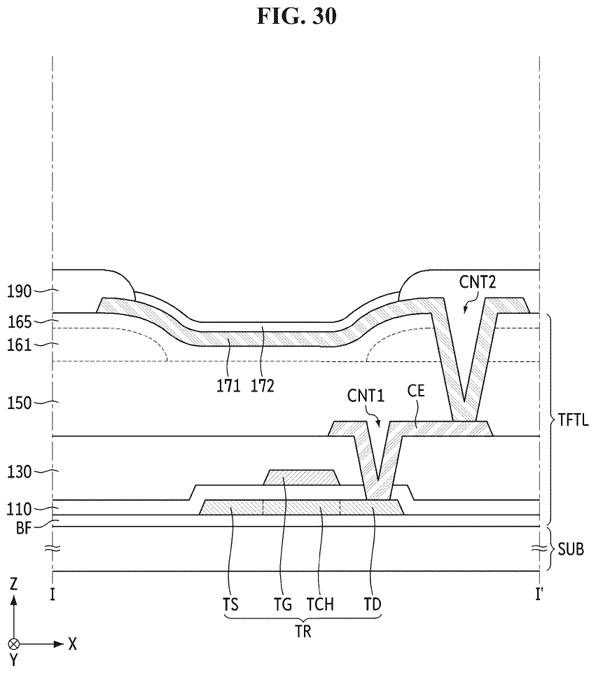

Referring to FIG. 30, the light-emitting layer 172 may be formed on the pixel electrode 171. The light-emitting layer 172 may be located only on a portion of the pixel electrode 171 exposed by the pixel-defining film 190.

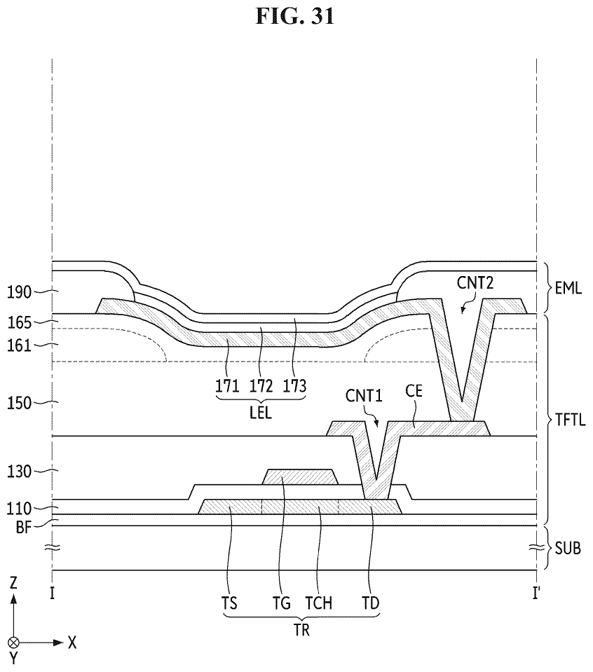

Referring to FIG. 31, the common electrode 173 may be formed on the light-emitting layer 172 and the pixel-defining film 190.

Subsequently, the encapsulation layer TFEL is formed on the common electrode 173 (S500 of FIG. 25).

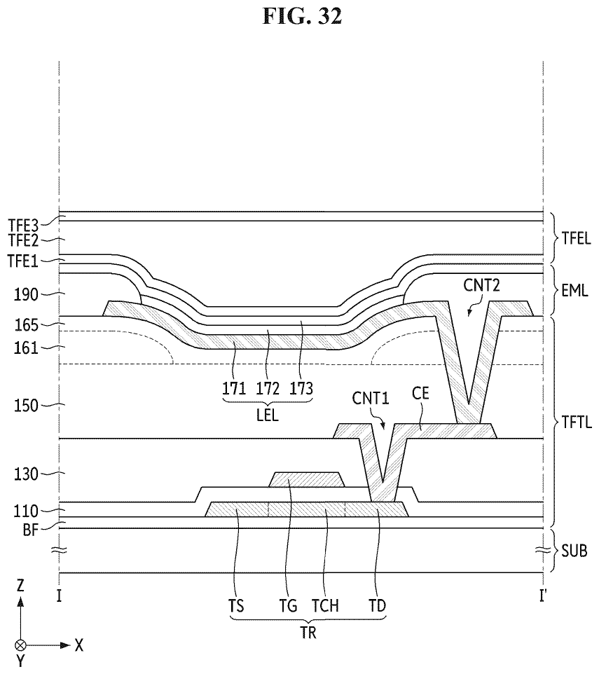

Referring to FIG. 32, the first inorganic encapsulation layer TFE1 may be formed on the common electrode 173. The organic encapsulation layer TFE2 may be located on the first inorganic encapsulation layer TFE1. The organic encapsulation layer TFE2 may planarize a step caused by the light-emitting element LEL and the pixel-defining film 190. The second inorganic encapsulation layer TFE3 may be located on the organic encapsulation layer TFE2.

Subsequently, the first touch-insulating film TINS1 is formed on the encapsulation layer TFEL (S600 of FIG. 25).

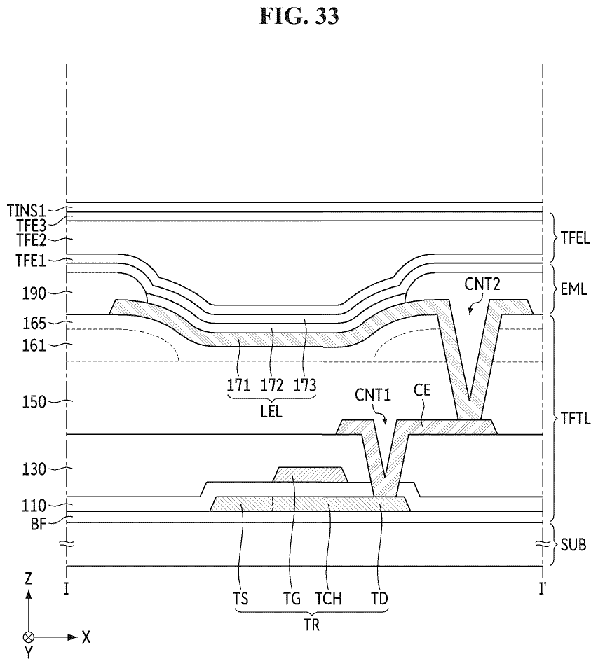

Referring to FIG. 33, the first touch-insulating film TINS1 may be formed on the second inorganic encapsulation layer TFE3. The first touch-insulating film TINS1 may be an inorganic film.

Subsequently, the scattering patterns SP1 to SP4 at least partially overlapping the pixel electrodes 171 are formed on the first touch-insulating film TINS1 (S700 of FIG. 25).

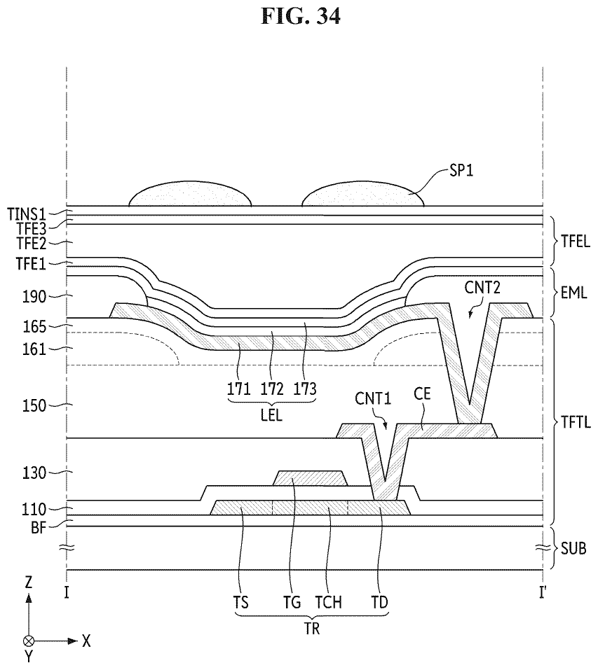

Referring to FIG. 34, the first scattering pattern SP1 may be formed on the first touch-insulating film TINS1. The first scattering pattern SP1 may overlap the light-emitting element LEL in the third direction (Z-axis direction). The second scattering pattern SP2, the third scattering pattern SP3, and the fourth scattering pattern SP4 may also be formed in the same manner as the first scattering pattern SP1.

Subsequently, the second touch-insulating film TINS2 and the third touch-insulating film TINS3 are formed on the scattering patterns SP1 to SP4 and the first touch-insulating film TINS1 (S800 of FIG. 25).

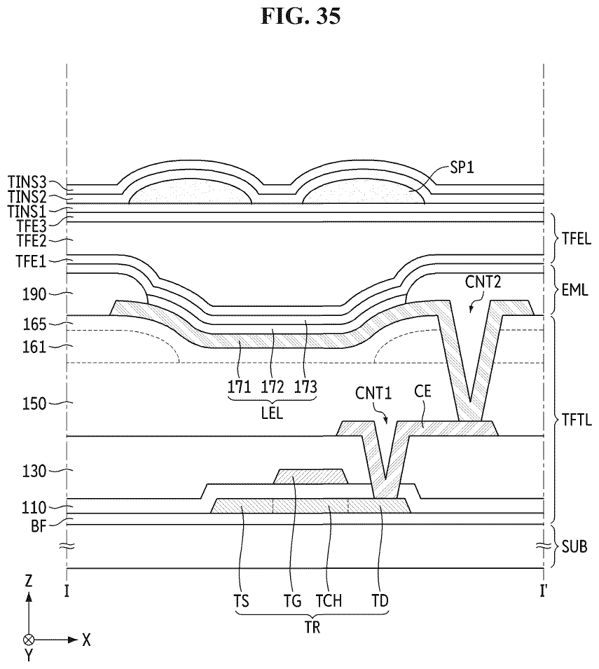

Referring to FIG. 35, the second touch-insulating film TINS2 may be formed on the first touch-insulating film TINS1 and the scattering patterns SP1 to SP4. The third touch-insulating film TINS3 may be formed on the second touch-insulating film TINS2.

Subsequently, the polarizing member POL is attached onto the third touch-insulating film TINS3 (S900 of FIG. 25).

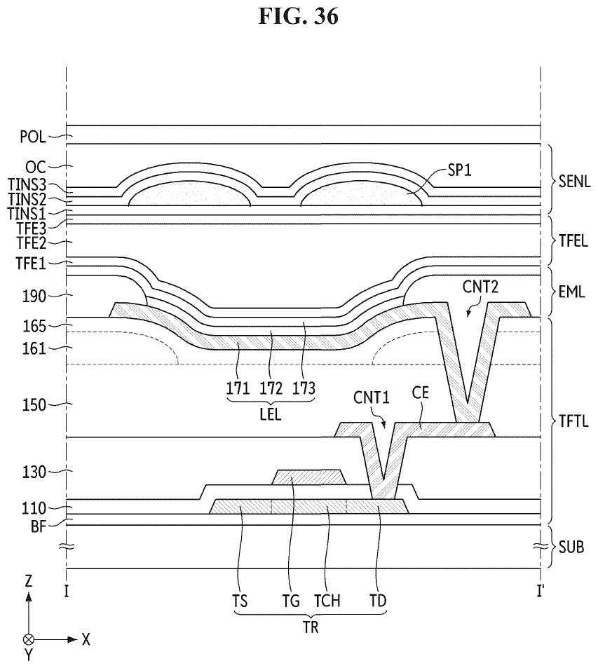

Referring to FIG. 36, the overcoat OC may be formed on the third touch-insulating film TINS3. The overcoat OC may planarize a step caused by the scattering patterns SP1 to SP4 and sensor electrodes.

The polarizing member POL may be attached onto the overcoat OC.

Subsequently, the adhesive member OCA is attached onto the polarizing member POL (S1000 of FIG. 25).

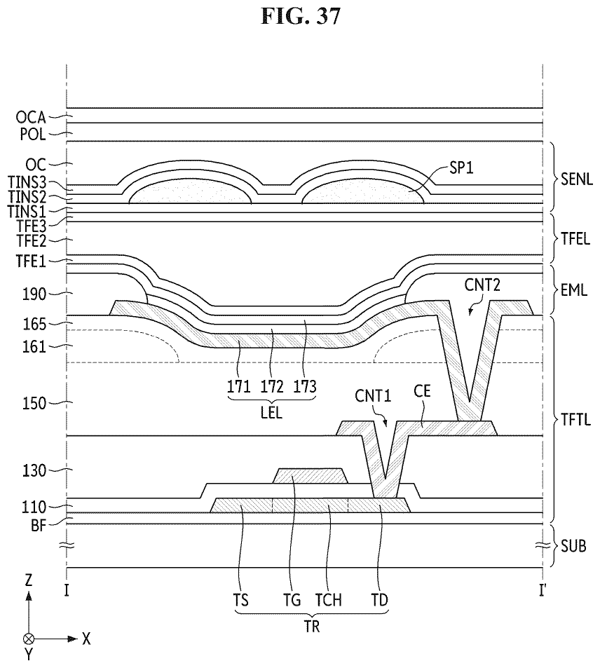

Referring to FIG. 37, the adhesive member OCA may be located on the polarizing member POL.

Subsequently, the window member WN is attached onto the adhesive member OCA (S1100 of FIG. 25).

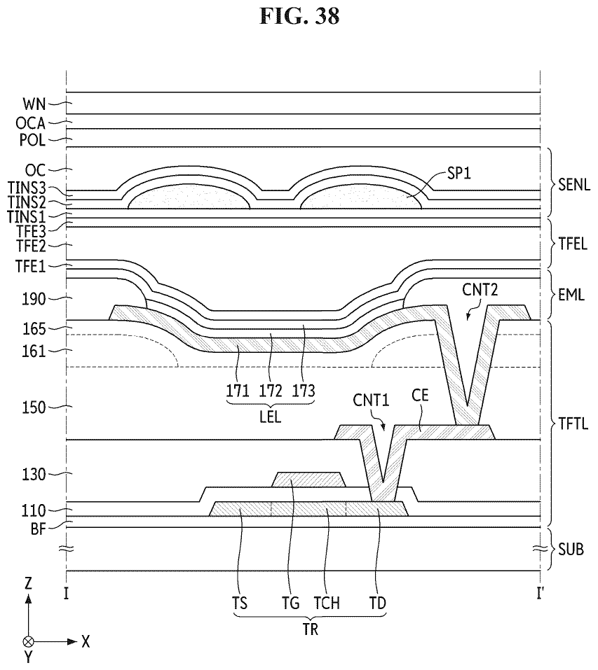

Referring to FIG. 38, the window member WN may be located on the adhesive member OCA.

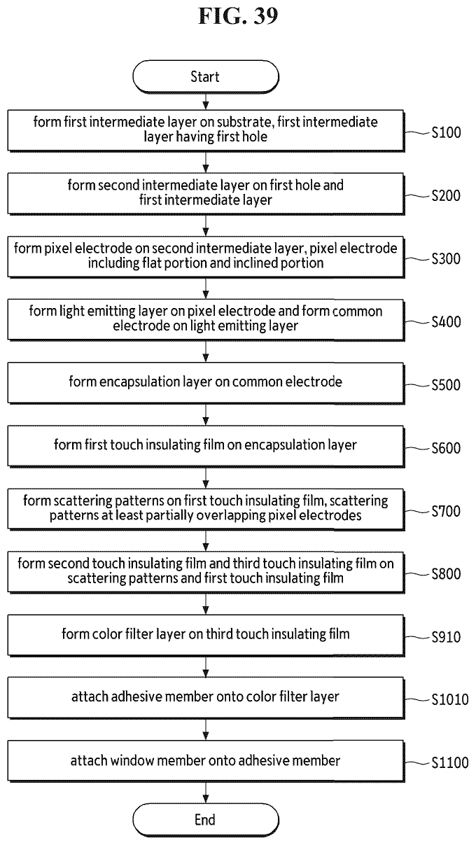

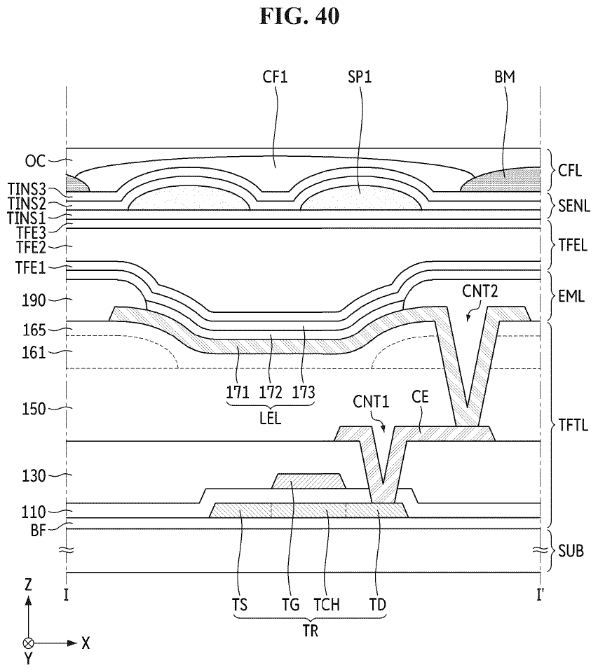

FIG. 39 is a flowchart for describing a manufacturing method of a display device according to some embodiments of the present disclosure. FIGS. 40 to 42 are cross-sectional views for describing respective processes of the manufacturing method of a display device of FIG. 39. A description of contents overlapping the contents described above will be omitted or briefly provided, and contents different from the contents described above will be mainly described.

The first intermediate layer 161 having a first hole H1 is formed on the substrate SUB (S100 of FIG. 39).

Subsequently, the second intermediate layer 165 is formed on the first hole H1 and the first intermediate layer 161 (S200 of FIG. 39).

Subsequently, the pixel electrode 171 including the flat portion FA and the inclined portion SA is formed on the second intermediate layer 165 (S300 of FIG. 39).

Subsequently, the light-emitting layer 172 is formed on the pixel electrode 171, and the common electrode 173 is formed on the light-emitting layer 172 (S400 of FIG. 39).

Subsequently, the encapsulation layer TFEL is formed on the common electrode 173 (S500 of FIG. 39).

Subsequently, the first touch-insulating film TINS1 is formed on the encapsulation layer TFEL (S600 of FIG. 39).

Subsequently, the scattering patterns SP1 to SP4 at least partially overlapping the pixel electrodes 171 are formed on the first touch-insulating film TINS1 (S700 of FIG. 39).

Subsequently, the second touch-insulating film TINS2 and the third touch-insulating film TINS3 are formed on the scattering patterns SP1 to SP4 and the first touch-insulating film TINS1 (S800 of FIG. 39).

Subsequently, the color filter layer CFL is formed on the third touch-insulating film TINS3 (S910 of FIG. 39).

Referring to FIG. 40, the color filter layer CFL may be formed on the third touch-insulating film TINS3. The color filter layer CFL may include the color filters CF1 to CF3, the black matrix BM, and the overcoat OC. The black matrix BM may be formed on the third touch-insulating film TINS3. The color filters CF1 to CF3 may be formed on the third touch-insulating film TINS3 and the black matrix BM. The overcoat OC may be formed on the color filters CF1 to CF3 and the black matrix BM. The overcoat OC may planarize a step caused by the color filters CF1 to CF3 and the black matrix BM.

Subsequently, the adhesive member OCA is attached onto the color filter layer CFL (S1010 of FIG. 39).

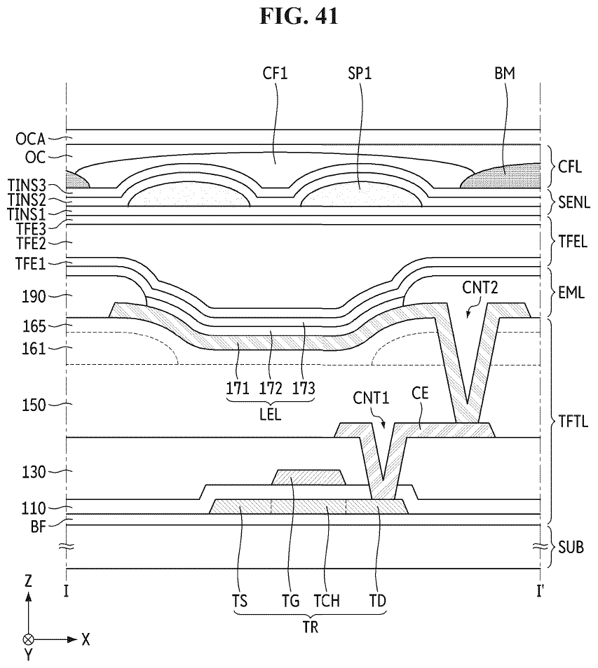

Referring to FIG. 41, the adhesive member OCA may be located on the overcoat OC.

Subsequently, the window member WN is attached onto the adhesive member OCA (S1100 of FIG. 39).

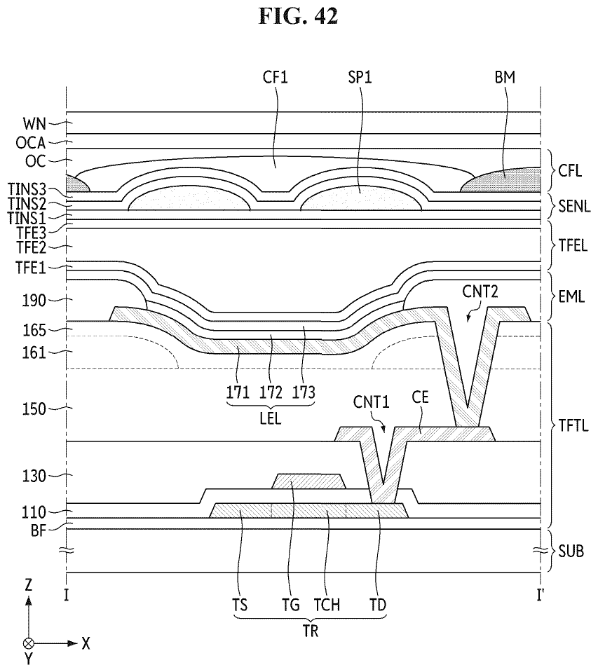

Referring to FIG. 42, the window member WN may be located on the adhesive member OCA.

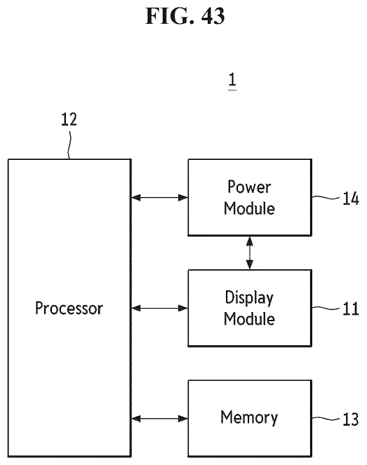

FIG. 43 is a block diagram for describing an electronic device including a display device according to some embodiments of the present disclosure.

Referring to 43, an electronic device 1 according to one or more embodiments may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), or a controller.

The memory 13 may store data information required for an operation of the processor 12 or the display module 11. When the processor 12 executes an application stored in the memory 13, an image data signal and/or an input control signal may be transmitted to the display module 11, and the display module 11 may process the received signal and output image information through a display screen.

The power module 14 may include a power supply module, such as a power adapter or a battery device, and a power conversion module for converting power supplied by the power supply module to generate power required for an operation of the electronic device 1.

At least one of the respective components of the above-described electronic device 1 may be included in the display device according to the above-described embodiments. In addition, some of individual modules functionally included in one module may be included in the display device, and the others of the individual modules may be provided separately from the display device. For example, the display device may include the display module 11, and the processor 12, the memory 13, and the power module 14 may be provided in the form of other devices within the electronic device 1 rather than the display device.

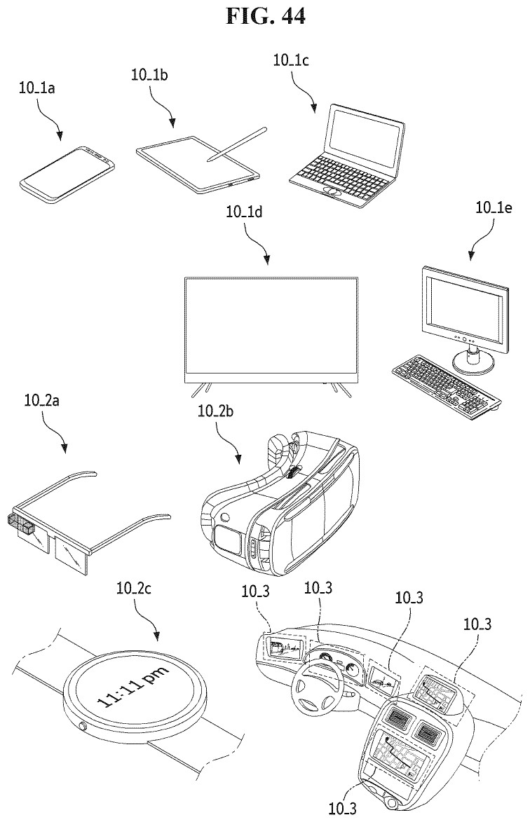

FIG. 44 is an illustrative diagram for describing an electronic device including a display device according to some embodiments of the present disclosure.

Referring to FIG. 44, various electronic devices to which the display device according to embodiments is applied may include not only image display electronic devices, such as a smartphone 10_1a, a tablet PC 10_1b, a laptop computer 10_1c, a television (TV) 10_1d, and a monitor 10_1e for a desktop computer, but also wearable electronic devices including display modules, such as a smart glasses 10_2a, a head-mounted display 10_2b, and a smart watch 10_2c, and vehicle electronic devices 10_3 including display modules, such as a center information display (CID) located on an instrument board, a center fascia, or a dashboard of a vehicle and a room mirror display.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims, with functional equivalents thereof to be included therein.

What is claimed is:

1. A display device comprising:
a substrate;
pixel electrodes above the substrate;
a pixel-defining film exposing portions of the pixel electrodes and defining emission areas;
light-emitting layers above the pixel electrodes in the emission areas;
a common electrode above the pixel-defining film and the light-emitting layers;
an encapsulation layer above the common electrode and comprising at least one organic film and at least one inorganic film; and
scattering patterns respectively in the emission areas at edges of the emission areas.

2. The display device of claim 1, wherein inner circumferences of the scattering patterns are inside the emission areas in plan view, and
wherein outer circumferences of the scattering patterns are outside the emission areas in plan view.

3. The display device of claim 2, further comprising:
a touch-sensing layer above the encapsulation layer and comprising inorganic insulating layers and sensor electrodes;
a reflection reduction member above the touch-sensing layer for reducing a reflection amount of incident external light;
a window member above the reflection reduction member; and
an adhesive member between the reflection reduction member and the window member,
wherein the pixel electrodes comprise:
a flat portion parallel to the substrate at a central portion of a corresponding one of the pixel electrodes; and
an inclined portion around the flat portion.

4. The display device of claim 3, wherein the scattering patterns are between the inorganic insulating layers.

5. The display device of claim 3, wherein the scattering patterns are on the inorganic insulating layers.

6. The display device of claim 3, wherein the scattering patterns are between the touch-sensing layer and the reflection reduction member.

7. The display device of claim 3, wherein the reflection reduction member comprises a polarizing member, and
wherein the scattering patterns are on one surface of the polarizing member.

8. The display device of claim 3, wherein the reflection reduction member comprises color filters, and
wherein the scattering patterns are on the color filters.

9. The display device of claim 3, wherein the scattering patterns are between the reflection reduction member and the adhesive member.

10. The display device of claim 3, wherein the scattering patterns are between the adhesive member and the window member.

11. The display device of claim 3, wherein the reflection reduction member comprises a black matrix around the emission areas in plan view, and
wherein the scattering patterns are spaced from the black matrix.

12. The display device of claim 3, wherein a shortest distance between one of the outer circumferences of one of the scattering patterns overlapping one of the pixel electrodes and an edge of the flat portion of the one of the pixel electrodes is a first straight line, and
wherein a first angle between a thickness direction of the substrate and the first straight line is about 5° to about 45°.

13. The display device of claim 12, wherein a distance between one of the inner circumferences of the one of the scattering patterns and the edge of the flat portion of the one of the pixel electrodes that is furthest therefrom is a second straight line, and
wherein a second angle between the thickness direction and the second straight line is substantially equal to the first angle.

14. The display device of claim 1, wherein the scattering patterns comprise organic materials comprising scattering particles.

15. An electronic device comprising:
a processor for transmitting an image data signal for displaying an image; and
a display module for receiving the image data signal and for displaying the image, and comprising:
a substrate;
pixel electrodes above the substrate;
a pixel-defining film exposing portions of the pixel electrodes and defining emission areas;
light-emitting layers above the pixel electrodes in the emission areas;
a common electrode above the pixel-defining film and the light-emitting layers;
an encapsulation layer above the common electrode and comprising at least one organic film and at least one inorganic film; and
scattering patterns respectively in the emission areas, and comprising inner circumferences respectively inside the emission areas, and outer circumferences respectively outside the emission areas.

16. A manufacturing method of a display device, the method comprising:
sequentially forming a pixel electrode, a light-emitting layer, and a common electrode above a substrate;
forming an encapsulation layer above the common electrode;
forming a first inorganic insulating film above the encapsulation layer; and
forming a scattering pattern above the first inorganic insulating film and at least partially overlapping the pixel electrode.

17. The manufacturing method of claim 16, further comprising:
forming a second inorganic insulating film and a third inorganic insulating film above the scattering pattern and the first inorganic insulating film;
attaching a polarizing member onto the third inorganic insulating film;
attaching an adhesive member onto the polarizing member; and
attaching a window member onto the adhesive member.

18. The manufacturing method of claim 16, further comprising:
forming a second inorganic insulating film and a third inorganic insulating film above the scattering pattern and the first inorganic insulating film;
forming a color filter layer comprising color filters above the third inorganic insulating film;
attaching an adhesive member onto the color filter layer; and
attaching a window member onto the adhesive member.

19. The manufacturing method of claim 16, wherein the forming of the pixel electrode, the light-emitting layer, and the common electrode comprises:
forming a first intermediate layer defining a first hole above the substrate;
forming a second intermediate layer above the first hole and the first intermediate layer;
forming the pixel electrode comprising a flat portion and an inclined portion above the second intermediate layer;
forming the light-emitting layer above the pixel electrode; and
forming the common electrode on the light-emitting layer.

20. The manufacturing method of claim 19, wherein the first hole overlaps the pixel electrode in a thickness direction of the substrate.
